(19) United States
(12) Patent Application Publication
(10) Pub. No.: US 2025/0164977 A1
(43) Pub. Date: May 22, 2025

(54) SUBSTRATE SUPPORT DEVICE, CLEANING DEVICE, DEVICE AND METHOD FOR CALCULATING ROTATION SPEED OF SUBSTRATE, AND MACHINE LEARNING DEVICE

(71) Applicant: EBARA CORPORATION, Tokyo (JP)

(72) Inventors: Michiaki MATSUDA, Tokyo (JP); Mitsuru MIYAZAKI, Tokyo (JP); Hisajiro NAKANO, Tokyo (JP); Yusuke WATANABE, Tokyo (JP)

(21) Appl. No.: 18/294,110

(22) PCT Filed: Jul. 29, 2022
(86) PCT No.: PCT/JP2022/029219

§ 371 Date: Jan. 31, 2024

(30) Foreign Application Priority Data
Aug. 5, 2021 (JP) 2021-128901

(51) Int. Cl. G05B 19/418; B24B 37/04

(52) U.S. Cl. CPC G05B 19/41875; B24B 37/042; G05B 2219/34465

(57) ABSTRACT

A substrate support device includes: a plurality of rollers that is arranged inside a housing and holds an outer edge of a substrate; a rotation drive unit that rotates the substrate by rotationally driving the plurality of rollers; a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller; a detection sensor that is arranged outside the housing, detects at least one of sound, vibration, and strain occurring from the housing, and outputs a signal corresponding thereto; and a rotation speed calculation section that calculates a rotation speed of the substrate, based on the signal outputted from the detection sensor.

### TECHNICAL FIELD

The present disclosure relates to a substrate support device, a cleaning device, a device and a method for calculating a rotation speed of a substrate, and a machine learning device.

### BACKGROUND ART

In the process of manufacturing a semiconductor device, various processes, such as film formation, etching, and polishing, are conducted on a surface of a substrate such as a semiconductor wafer. Before and after the various processes, a substrate cleaning process is conducted because the surface of the substrate needs to be kept clean. In the substrate cleaning process, a cleaning machine is widely used that rotates the substrate by rotationally driving a plurality of rollers while holding the outer edge of the substrate with the rollers, and cleans the substrate by pressing a cleaning member against the rotating substrate.

As described above, in cleaning machines that hold the outer edge of a substrate and rotate the substrate by using a plurality of rollers, contamination (particles and the like) on a surface of the substrate is removed by scrubbing the surface of the substrate with a cleaning member while applying a predetermined pressure to the surface of the substrate. Accordingly, a slip may occur between the substrate and the rollers, and the rotation speed of the substrate may fall below a set rotation speed, in some cases.

Moreover, also in other processes than the substrate cleaning process of cleaning a substrate, a more improved method for calculating the rotation speed of the substrate is sought when the substrate is held and rotated by using rollers.

Currently, in order to determine whether or not a slip occurs between a substrate and rollers, there is a method in which the actual rotation speed of the substrate is measured by bringing an idler into contact with the outer edge of the substrate. However, since cleanliness performance may lower due to adhesion of contamination from the idler, or erroneous measurement may result from a slip occurring between the substrate and the idler in the method, a method for measuring the actual rotation speed of a substrate without using an idler is desired.

Japanese Patent Laid-Open No. 2003-77881 (patent literature 1) discloses a technique in which vibrations occurring in rollers due to a notch on a rotationally driven substrate hitting the rollers are detected by a vibration sensor attached to the rollers, and it is determined, based on detection of the vibrations, whether or not a slip occurs between the substrate and the rollers.

### SUMMARY OF INVENTION

However, the patent literature 1 has a problem with maintainability because the vibration sensor for detecting vibrations is directly attached to the rollers. To enhance maintainability, it is conceivable to attach the sensor to an outer panel of a housing from outside. However, in such a case, there arises a problem that sound or vibration occurring in external equipment outside the housing, or sound or vibration occurring inside the housing irrespective of the rotation speed of the substrate (for example, sound or vibration occurring due to cleaning liquid flowing, or the like), is mixed in as noise.

For a substrate support device that holds the outer edge of a substrate and rotates the substrate by using a plurality of rollers, provision of a technique is desired by which the rotation speed of the substrate can be obtained with accuracy while maintainability can be enhanced. Moreover, for a substrate support device that rotates a substrate while supporting the substrate, provision of a technique for estimating whether or not rotation abnormality occurs, or what level the rotation abnormality is at, is also desired.

### Solution to Problem

A substrate support device according to one aspect of the present disclosure includes: a plurality of rollers that is arranged inside a housing and holds an outer edge of a substrate; a rotation drive unit that rotates the substrate by rotationally driving the plurality of rollers; a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller; a detection sensor that is arranged outside the housing, detects at least one of sound, vibration, and strain occurring from the housing, and outputs a signal corresponding thereto; and a rotation speed calculation section that calculates a rotation speed of the substrate, based on the signal outputted from the detection sensor.

### BRIEF DESCRIPTION OF DRAWINGS

FIG. 1 is a plane view showing an entire configuration of a polishing device according to an embodiment.

FIG. 2 is a side view showing an internal configuration of a cleaning device according to an embodiment.

FIG. 3 is a plane view showing an arrangement of rollers in the cleaning device shown in FIG. 2.

FIG. 4 is a side view for describing a modification of an arrangement of a vibration transmission mechanism.

FIG. 5 is a side view for describing another modification of the arrangement of the vibration transmission mechanism.

FIG. 6A is a side view showing a modification of a configuration of the vibration transmission mechanism.

FIG. 6B is a side view showing another modification of the configuration of the vibration transmission mechanism.

FIG. 6C is a side view showing another modification of the configuration of the vibration transmission mechanism.

FIG. 6D is a side view showing another modification of the configuration of the vibration transmission mechanism.

FIG. 6E is a side view showing another modification of the configuration of the vibration transmission mechanism.

FIG. 6F is a side view showing another modification of the configuration of the vibration transmission mechanism.

FIG. 6G is a side view showing another modification of the configuration of the vibration transmission mechanism.

FIG. 6H is a side view showing another modification of the configuration of the vibration transmission mechanism.

FIG. 6I is a side view showing another modification of the configuration of the vibration transmission mechanism.

FIG. 6J is a side view showing another modification of the configuration of the vibration transmission mechanism.

FIG. 6K is a side view showing another modification of the configuration of the vibration transmission mechanism.

FIG. 6L is a side view showing another modification of the configuration of the vibration transmission mechanism.

FIG. 6M is a side view showing another modification of the configuration of the vibration transmission mechanism.

FIG. 6N is a side view showing another modification of the configuration of the vibration transmission mechanism.

FIG. 7A is a plane view showing another modification of the configuration of the vibration transmission mechanism.

FIG. 7B is a plane view for describing operation of the vibration transmission mechanism shown in FIG. 7A.

FIG. 7C is a plane view showing another modification of the configuration of the vibration transmission mechanism.

FIG. 7D is a plane view showing another modification of the configuration of the vibration transmission mechanism.

FIG. 7E is a plane view showing another modification of the configuration of the vibration transmission mechanism.

FIG. 8A is a plane view showing another modification of the arrangement of the vibration transmission mechanism.

FIG. 8B is a plane view showing another modification of the arrangement of the vibration transmission mechanism.

FIG. 8C is a plane view showing another modification of the arrangement of the vibration transmission mechanism.

FIG. 8D is a plane view showing another modification of the arrangement of the vibration transmission mechanism.

FIG. 8E is a plane view showing another modification of the arrangement of the vibration transmission mechanism.

FIG. 8F is a plane view showing another modification of the arrangement of the vibration transmission mechanism.

FIG. 8G is a plane view showing another modification of the arrangement of the vibration transmission mechanism.

FIG. 9 is a diagram showing an example of a flow of signal processing of calculating the rotation speed of a substrate, based on sound or vibration detected by a detection sensor.

FIG. 10 is a block diagram showing a configuration of calculating the rotation speed of a substrate, based on sound or vibration detected by the detection sensor.

FIG. 11A is a diagram showing an example of a flow of signal processing of adjusting the amount of compression of an elastic object.

FIG. 11B is a diagram showing a modification of a flow of signal processing of adjusting the active length of the elastic object.

FIG. 11C is a diagram showing a modification of the flow of signal processing of adjusting the amount of compression of the elastic object.

FIG. 11D is a diagram showing a modification of the flow of signal processing of adjusting the active length of the elastic object.

FIG. 12A is an example of a graph showing raw waveforms of a sound or vibration signal detected by the detection sensor at normal time.

FIG. 12B is an example of a graph showing waveforms, after passing through a BPF or an HPF, of the sound or vibration signal detected by the detection sensor at normal time.

FIG. 12C is an example of a graph showing waveforms, after an absolute value conversion process, of the sound or vibration signal detected by the detection sensor at normal time.

FIG. 12D is an example of a graph showing waveforms, after passing through an LPF, of the sound or vibration signal detected by the detection sensor at normal time.

FIG. 12E is an example of a graph showing a result of FFT analysis of the sound or vibration signal detected by the detection sensor at normal time.

FIG. 13A is an example of a graph showing, in a superimposing manner, raw waveforms of sound or vibration signals detected by the detection sensor at normal time and at abnormal time.

FIG. 13B is an example of a graph showing, in a superimposing manner, waveforms, after passing through the BPF or the HPF, of the sound or vibration signals detected by the detection sensor at normal time and at abnormal time.

FIG. 13C is an example of a graph showing, in a superimposing manner, waveforms, after the absolute value conversion process, of the sound or vibration signals detected by the detection sensor at normal time and at abnormal time.

FIG. 13D is an example of a graph showing, in a superimposing manner, waveforms, after passing through the LPF, of the sound or vibration signals detected by the detection sensor at normal time and at abnormal time.

FIG. 13E is an example of a graph showing, in a superimposing manner, results of FFT analysis of the sound or vibration signals detected by the detection sensor at normal time and at abnormal time.

FIG. 14 is a diagram showing an example of a functional block diagram showing an example of a functional configuration of a numerical control system according to an embodiment.

FIG. 15 is a diagram showing an example of a trained model provided from a machine learning device to an inference device.

### DESCRIPTION OF EMBODIMENTS

A substrate support device according to a first aspect of an embodiment includes: a plurality of rollers that is arranged inside a housing and holds an outer edge of a substrate; a rotation drive unit that rotates the substrate by rotationally driving the plurality of rollers; a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller; a detection sensor that is arranged outside the housing, detects at least one of sound, vibration, and strain occurring from the housing, and outputs a signal corresponding thereto; and a rotation speed calculation section that calculates a rotation speed of the substrate, based on the signal outputted from the detection sensor.

According to such an aspect, since the detection sensor is arranged outside the housing, maintainability is good. Moreover, since the vibration transmission mechanism is installed in such a manner as to extend from any of the rollers or the rotation drive unit up to an outer panel of the housing and transmits, to the housing, vibrations occurring due to the notch or the orientation flat on the outer edge of the substrate hitting the roller, the vibrations occurring due to the notch or the orientation flat on the outer edge of the substrate hitting the roller are easily transmitted to the detection sensor even though the detection sensor is arranged outside the housing, so that the S/N ratio can be improved. Accordingly, accuracy in detection of the vibrations occurring due to the notch or the orientation flat on the outer edge of the substrate hitting the roller can be enhanced, whereby it is possible to obtain the rotation speed of the substrate with accuracy while enhancing maintainability. Moreover, according to such an aspect, since the detection sensor is arranged outside the housing, waterproof treatment is not required for the detection sensor, and further, even if burnable cleaning liquid is used inside the housing, explosion-proof treatment is not required for the detection sensor.

A substrate support device according to a second aspect of the embodiment is the substrate support device according to the first aspect, wherein natural frequency of the vibration transmission mechanism is adjusted to correspond to frequency of the vibrations occurring due to the notch or the orientation flat on the outer edge of the substrate hitting the roller.

According to such an aspect, since vibrations in bands around the natural frequency are amplified and vibrations in higher frequency bands are damped in the vibration transmission mechanism, the vibrations occurring due to the notch or the orientation flat on the outer edge of the substrate hitting the roller can be emphasized and transmitted to the housing, so that accuracy in detection of the vibrations by the detection sensor arranged outside the housing can be enhanced.

A substrate support device according to a third aspect of the embodiment is the substrate support device according to the first or second aspect, wherein part in a longitudinal direction of the vibration transmission mechanism is configured by using an elastic object.

According to such an aspect, since the natural frequency of the vibration transmission mechanism decreases, only low-frequency vibrations can be made to be easily transmitted and emphasized.

A substrate support device according to a fourth aspect of the embodiment is the substrate support device according to the third aspect, wherein the elastic object is compressed.

According to such an aspect, since the stiffness of the elastic object increases and reflection at a joint portion thereof decreases, loss in vibration transmission can be reduced.

A substrate support device according to a fifth aspect of the embodiment is the substrate support device according to the third or fourth aspect, including an adjustment mechanism that adjusts an amount of compression or an active length of the elastic object.

According to such an aspect, the natural frequency of the vibration transmission mechanism can be freely adjusted by adjusting the amount of compression or the active length of the elastic object by using the adjustment mechanism.

A substrate support device according to a sixth aspect of the embodiment is the substrate support device according to the fifth aspect, wherein the adjustment mechanism refers to a database in which a correspondence between a rotation speed and an amount of compression or an active length is stored beforehand, and adjusts the amount of compression or the active length of the elastic object to the amount of compression or the active length stored in the database according to a set value of the rotation speed of the substrate.

According to such an aspect, the amount of compression or the active length of the elastic object can be adjusted to an appropriate value according to the set value of the rotation speed of the substrate, whereby it is possible to appropriately emphasize and transmit to the housing the vibrations occurring due to the notch or the orientation flat on the outer edge of the substrate hitting the roller.

A substrate support device according to a seventh aspect of the embodiment is the substrate support device according to the fifth aspect, wherein the adjustment mechanism adjusts the amount of compression or the active length of the elastic object, according to a value detected by a first strain gauge attached to part in the longitudinal direction of the vibration transmission mechanism.

According to such an aspect, the amount of compression or the active length of the elastic object can be adjusted to an appropriate value according to the value detected by the first strain gauge, whereby it is possible to appropriately emphasize and transmit to the housing the vibrations occurring due to the notch or the orientation flat on the outer edge of the substrate hitting the roller.

A substrate support device according to an eighth aspect of the embodiment is the substrate support device according to the fifth aspect, wherein the adjustment mechanism adjusts the amount of compression or the active length of the elastic object, according to frequency of the signal outputted from the detection sensor.

According to such an aspect, the amount of compression or the active length of the elastic object can be adjusted to an appropriate value according to the frequency of at least one of sound, vibration, and strain detected by the detection sensor, whereby it is possible to appropriately emphasize and transmit to the housing the vibrations occurring due to the notch or the orientation flat on the outer edge of the substrate hitting the roller.

A substrate support device according to a ninth aspect of the embodiment is the substrate support device according to the eighth aspect, wherein the adjustment mechanism refers to a database in which a correspondence between a rotation speed and an amount of compression or an active length is stored beforehand, and adjusts the amount of compression or the active length of the elastic object to the amount of compression or the active length stored in the database according to the rotation speed calculated by the rotation speed calculation section.

According to such an aspect, the amount of compression or the active length of the elastic object can be adjusted to an appropriate value according to the actual rotation speed of the substrate, whereby it is possible to appropriately emphasize and transmit to the housing the vibrations occurring due to the notch or the orientation flat on the outer edge of the substrate hitting the roller.

A substrate support device according to a tenth aspect of the embodiment is the substrate support device according to any one of the first to ninth aspects, wherein the detection sensor is at least one of a microphone, a vibration sensor, and a second strain gauge attached to the housing.

A substrate support device according to an eleventh aspect of the embodiment is the substrate support device according to any one of the first to tenth aspects, wherein at least an end portion, on a side to the roller or the rotation drive unit, of the vibration transmission mechanism is oriented in such a manner as to extend, in a plane view, in a direction perpendicular to a tangent line to the substrate at a point where the substrate is in contact with the roller.

Vibrations occurring due to reaction force received by the roller from the substrate are in the direction perpendicular to the tangent line to the substrate at the point where the substrate is in contact with the roller. Accordingly, in such an aspect, the vibration transmission mechanism can efficiently transmit, to the housing, the vibrations occurring due to the notch or the orientation flat on the outer edge of the substrate hitting the roller.

A substrate support device according to a twelfth aspect of the embodiment is the substrate support device according to any one of the first to eleventh aspects, wherein the rotation speed calculation section calculates the rotation speed of the substrate, based on a fundamental wave and a harmonic of the signal.

When the frequency of the signal corresponding to at least one of sound, vibration, and strain fluctuates, higher harmonics have larger amounts of fluctuation in peak waveform (for example, the amount of fluctuation of 1% in a fundamental wave of 100 Hz is 1 Hz, and the amount of fluctuation of 1% in a second harmonic of 200 Hz is 2 Hz, which is twice the amount of fluctuation in the fundamental wave). Accordingly, according to such an aspect, the rotation speed of the substrate can be obtained with greater accuracy by calculating the rotation speed of the substrate by using not only the fundamental wave of the signal but also a harmonic thereof.

A substrate support device according to a thirteenth aspect of the embodiment is the substrate support device according to any one of the first to twelfth aspects, further including a rotation speed setting section that sets, on the rotation drive unit, a set value of the rotation speed of the substrate, wherein the rotation speed calculation section calculates the rotation speed of the substrate, with the set value acquired from the rotation speed setting section taken into consideration.

A substrate support device according to a fourteenth aspect of the embodiment is the substrate support device according to any one of the first to thirteenth aspects, further including a display control section that causes a display to display the rotation speed calculated by the rotation speed calculation section.

A substrate support device according to a fifteenth aspect of the embodiment is the substrate support device according to the fourteenth aspect, wherein the display control section averages a plurality of past rotation speeds calculated by the rotation speed calculation section and causes the display to display a result thereof.

A substrate support device according to a sixteenth aspect of the embodiment is the substrate support device according to any one of the first to fifteenth aspects, further including an abnormality determination section that determines whether or not there is abnormality, based on the rotation speed calculated by the rotation speed calculation section.

A substrate support device according to a seventeenth aspect of the embodiment is the substrate support device according to the sixteenth aspect, wherein the abnormality determination section determines whether or not there is abnormality, based on an average value of a plurality of past rotation speeds calculated by the rotation speed calculation section.

A substrate support device according to an eighteenth aspect of the embodiment is the substrate support device according to the sixteenth or seventeenth aspect, further including an abnormality alarm activation section that, when it is determined by the abnormality determination section that there is abnormality, activates an alarm about the abnormality and/or instructs the rotation drive unit to stop.

A substrate support device according to a nineteenth aspect of the embodiment is the substrate support device according to any one of the sixteenth to eighteenth aspects, wherein the abnormality determination section calculates a difference or a ratio between the rotation speed calculated by the rotation speed calculation section and the set value acquired from the rotation speed setting section and, when the difference or the ratio exceeds a predetermined threshold value, determines that there is abnormality.

A substrate support device according to a twentieth aspect of the embodiment is the substrate support device according to any one of the sixteenth to nineteenth aspects, wherein the abnormality determination section determines that there is abnormality when the rotation speed calculated by the rotation speed calculation section is zero and the set value acquired from the rotation speed setting section is not zero, or when an abnormal signal is outputted from the detection sensor.

A substrate support device according to a twenty first aspect of the embodiment is the substrate support device according to any one of the sixteenth to twentieth aspects, wherein the abnormality determination section determines whether or not there is abnormality, with fluctuations in current flowing in a motor rotating a cleaning member, taken into consideration.

A substrate support device according to a twenty second aspect of the embodiment is the substrate support device according to any one of the fifteenth to twenty first aspects, wherein the abnormality determination section determines whether or not there is abnormality, with fluctuations in atmospheric pressure inside the housing, taken into consideration.

A substrate support device according to a twenty third aspect of the embodiment is the substrate support device according to the thirteenth aspect, wherein the rotation speed calculation section changes a cutoff frequency of a filter applied to the signal, according to the set value.

A cleaning device according to a twenty fourth aspect of the embodiment includes: a plurality of rollers that holds an outer edge of a substrate; a rotation drive unit that rotates the substrate by rotationally driving the plurality of rollers; a cleaning member that comes into direct contact with the substrate and cleans the substrate; a cleaning liquid supply nozzle that supplies cleaning liquid onto the substrate; a housing that houses the plurality of rollers, the cleaning member, and the cleaning liquid supply nozzle; a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller; a detection sensor that is arranged outside the housing, detects at least one of sound, vibration, and strain occurring from the housing, and outputs a signal corresponding thereto; and a rotation speed calculation section that calculates a rotation speed of the substrate, based on the signal outputted from the detection sensor.

A device according to a twenty fifth aspect of the embodiment is a device that, in a substrate support device, calculates a rotation speed of a substrate, the substrate support device including: a plurality of rollers that is arranged inside a housing and holds an outer edge of the substrate; and a rotation drive unit that rotates the substrate by rotationally driving the plurality of rollers, the device including: a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller; a detection sensor that is arranged outside the housing, detects at least one of sound, vibration, and strain occurring from the housing, and outputs a signal corresponding thereto; and a rotation speed calculation section that calculates the rotation speed of the substrate, based on the signal outputted from the detection sensor.

A method according to a twenty sixth aspect of the embodiment is a method for calculating a rotation speed of a substrate for a substrate support device, the substrate support device including: a plurality of rollers that is arranged inside a housing and holds an outer edge of the substrate; and a rotation drive unit that rotates the substrate by rotationally driving the plurality of rollers, the method including: by a vibration transmission mechanism installed in such a manner as to extend from any of the rollers or the rotation drive unit up to the housing, transmitting vibrations to the housing, the vibrations occurring due to a notch or an orientation flat on the outer edge of the substrate hitting the roller; by a detection sensor arranged outside the housing, detecting at least one of sound, vibration, and strain occurring from the housing and outputting a signal corresponding thereto; and calculating the rotation speed of the substrate, based on the signal outputted from the detection sensor.

A method according to a twenty seventh aspect of the embodiment is the method according to the twenty sixth aspect, further including adjusting at least one of material of, length of, cross-section shape of, and mass addition to the vibration transmission mechanism in such a manner that natural frequency of the vibration transmission mechanism corresponds to frequency of the vibrations occurring due to the notch or the orientation flat on the outer edge of the substrate hitting the roller.

A machine learning device according to a twenty eighth aspect of the embodiment includes: a data acquisition section that acquires, as input data, data obtained by a detection sensor based on at least one of sound, vibration, and strain that occur from a housing as a result of vibrations being transmitted to the housing via a vibration transmission mechanism, the vibrations occurring due to a notch or an orientation flat on an outer edge of a substrate hitting a roller when the substrate held at the outer edge thereof by the roller is rotationally driven inside the housing; a label acquisition section that acquires label data indicating a degree of rotation abnormality at a time of rotation of the substrate under a substrate rotation condition included in the input data; and a learning section that generates a trained model by performing supervised learning using the input data acquired by the input data acquisition section and the label data acquired by the label acquisition section.

According to such an aspect, for a substrate support device that rotates a substrate while supporting the substrate, it can be inferred with accuracy whether or not rotation abnormality occurs, or what level the rotation abnormality is at.

A machine learning device according to a twenty ninth aspect of the embodiment is the machine learning device according to the twenty eighth aspect, wherein the input data is a moving average value of data obtained by the detection sensor based on at least one of sound, vibration, and strain during a predetermined time period from a time earlier than a reference time until the reference time.

According to such an aspect, when it is inferred for a substrate support device that rotates a substrate while supporting the substrate, based on the data obtained by the detection sensor based on at least one of sound, vibration, and strain, whether or not rotation abnormality occurs, or what level the rotation abnormality is at, erroneous determination can be reduced, and accuracy can be further enhanced.

A machine learning device according to a thirtieth aspect of the embodiment is the machine learning device according to the twenty eighth aspect, wherein the learning section identifies which one of the notch and the orientation flat is a source of the vibrations at the time of rotation of the substrate, associates, with the degree of rotation abnormality, the data obtained by the detection sensor based on at least one of sound, vibration, and strain that occur from the housing and correspond to a type of the source, and performs learning by using the associated data for teaching data.

According to such an aspect, when it is inferred for a substrate support device that rotates a substrate while supporting the substrate what level the rotation abnormality is at, accuracy in determination can be automatically enhanced as a cumulative time period of use increases when the consecutive uses of the device continue.

Hereinafter, specific examples of an embodiment are described in detail with reference to the accompanying drawings. Note that throughout the following description and the drawings used in the following description, the same reference signs are used to denote parts that can be identically configured, and duplicate description will be omitted.

### <Substrate Treatment Device>

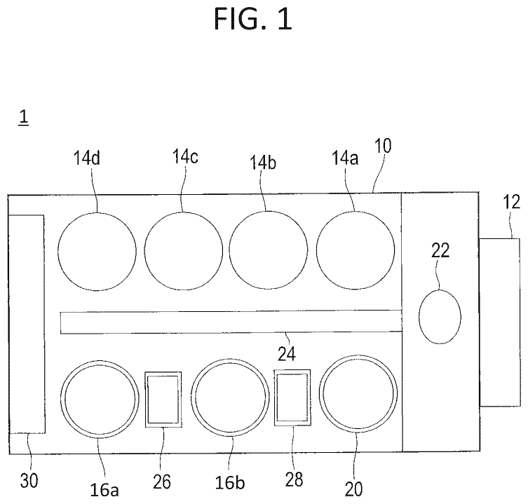

FIG. 1 is a plane view showing an entire configuration of a substrate treatment device (also referred to as a polishing device) 1 according to an embodiment.

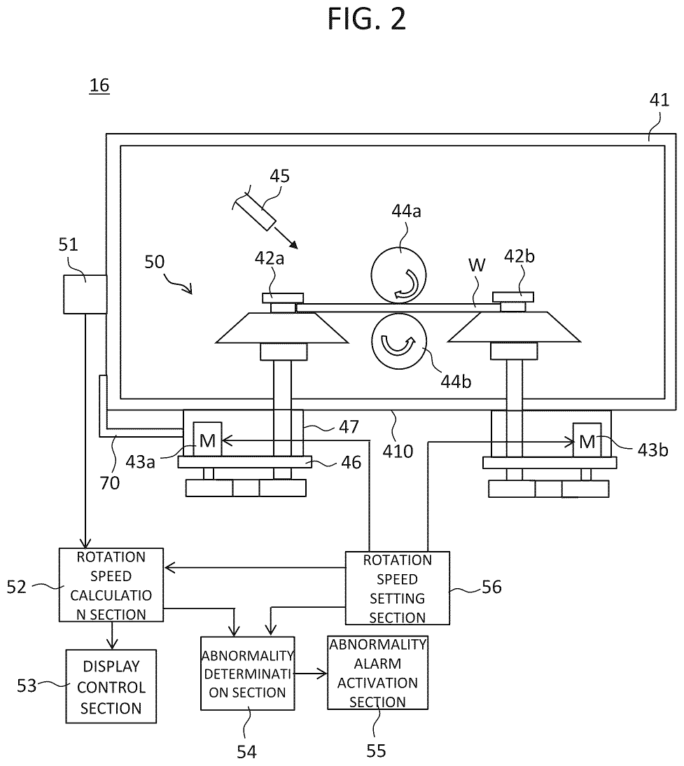

As shown in FIG. 1, the substrate treatment device 1 includes a housing 10 in an approximately rectangular shape, and a load port 12 on which a substrate cassette (not shown) stocked with a plurality of substrates W (see FIG. 2 and the like) is placed. The load port 12 is arranged next to the housing 10. On the load port 12, an open cassette, a SMIF (Standard Manufacturing Interface) pod, or a FOUP (Front Opening Unified Pod) can be loaded. SMIF pods and FOUPs are airtight containers that can house a substrate cassette inside and keep an environment independent of an external space by enclosing the substrate cassette with bulkheads. Examples of the substrate W include a semiconductor wafer and the like.

A plurality of (four, in the aspect depicted in FIG. 1) polishing units 14a to 14d, a first cleaning unit 16a and a second cleaning unit 16b that clean the substrates W after polished, and a drying unit 20 that dries the substrates W after cleaned are housed inside the housing 10. The polishing units 14a to 14d are lined along a longitudinal direction of the housing 10, and the cleaning units 16a, 16b and the drying unit 20 are also lined along the longitudinal direction of the housing 10.

A first transport robot 22 is arranged in an area enclosed by the load port 12, the polishing unit 14a positioned on a load port 12 side, and the drying unit 20. A transport unit 24 is arranged between an area in which the polishing units 14a to 14d are lined and an area in which the cleaning units 16a, 16b and the drying unit 20 are lined, in parallel with the longitudinal direction of the housing 10. The first transport robot 22 receives each substrate W before polished from the load port 12 and transfers the substrate W to the transport unit 24, and receives from the transport unit 24 each dried substrate W taken out of the drying unit 20.

A second transport robot 26 that receives and transfers each substrate W between the first cleaning unit 16a and the second cleaning unit 16b is arranged between the first cleaning unit 16a and the second cleaning unit 16b. A third transport robot 28 that receives and transfers each substrate W between the second cleaning unit 16b and the drying unit 20 is arranged between the second cleaning unit 16b and the drying unit 20.

Further, the substrate treatment device 1 is provided with a polishing control device 30 that controls actions of each equipment 14a to 14d, 16a, 16b, 22, 24, 26, 28. For the polishing control device 30, for example, a programmable logic controller (PLC) is used. Although the polishing control device 30 is arranged inside the housing 10 in the aspect depicted in FIG. 1, the arrangement is not limited thereto, and the polishing control device 30 may be arranged outside the housing 10.

For the first cleaning unit 16a and/or the second cleaning unit 16b, a roll cleaning device (a cleaning device 16 according to an embodiment, which will be described later) may be used that brings a roll cleaning member elongated in a straight line over an approximately entire length of the diameter of the substrate W into contact with a surface of a substrate W in the presence of cleaning liquid, and cleans by scrubbing the surface of the substrate W while causing the roll cleaning member to rotate; a pencil cleaning device (not shown) may be used that brings a columnar pencil cleaning member extending in a vertical direction into contact with a surface of a substrate W in the presence of cleaning liquid, and cleans by scrubbing the surface of the substrate W by moving the pencil cleaning member in one direction parallel with the surface of the substrate W while rotating the pencil cleaning member; a buff cleaning polishing device (not shown) may be used that brings a buff cleaning polishing member with an axis line of rotation extending in a vertical direction into contact with a surface of a substrate W in the presence of cleaning liquid, and cleans and polishes by scrubbing the surface of the substrate W by moving the buff cleaning polishing member in one direction parallel with the surface of the substrate W while rotating the buff cleaning polishing member; or a two-fluid jet cleaning device (not shown) may be used that cleans a surface of a substrate W by using a two-fluid jet. For the first cleaning unit 16a and/or the second cleaning unit 16b, any two or more of the roll cleaning device, the pencil cleaning device, the buff cleaning polishing device, and the two-fluid jet cleaning device may be used in combination.

The cleaning liquid includes a rinse liquid, such as deionized water (DIW), and a chemical liquid, such as an ammonia-hydrogen peroxide mixture (SC1), a hydrochloric acid-hydrogen peroxide mixture (SC2), a sulfuric acid-hydrogen peroxide mixture (SPM), a sulfuric acid-hydrogen peroxide-water mixture, or hydrofluoric acid. In the present embodiment, the cleaning liquid refers to either the rinse liquid or the chemical liquid, unless otherwise stated.

For the drying unit 20, a spin drying device may be used that dries a substrate W by ejecting isopropyl alcohol (IPA) steam toward the rotating substrate W from a spraying nozzle moving in one direction parallel with a surface of the substrate W, and further dries the substrate W by using centrifugal force by rotating the substrate W at high speed.

### <Cleaning Device>

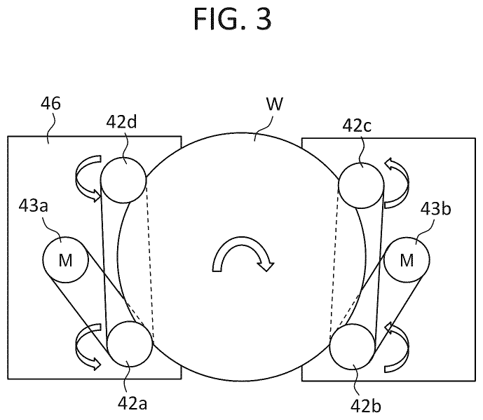

Next, the cleaning device 16 according to an embodiment is described. FIG. 2 is a side view showing an internal configuration of the cleaning device 16 according to the embodiment, and FIG. 3 is a plane view showing an arrangement of rollers 42a to 42d in the cleaning device 16. The cleaning device 16 according to the embodiment may be used for the first cleaning unit 16a and/or the second cleaning unit 16b in the above-described substrate treatment device 1.

As shown in FIGS. 2 and 3, the cleaning device 16 includes a housing 41 that defines a cleaning space in which cleaning of a substrate W is performed, a substrate support device 50 that supports and rotates the substrate W, cleaning members 44a, 44b that come into direct contact with the substrate W and cleans the substrate W, and a cleaning liquid supply nozzle 45 that supplies cleaning liquid onto the substrate W. Of such equipment, the substrate support device 50 is arranged inside the housing 41 and includes a plurality of (four, in the depicted example,) the rollers 42a to 42d that hold the outer edge of the substrate W and rotation drive units 43a, 43b that rotate the substrate W by rotationally driving the plurality of rollers 42a to 42d.

In the present embodiment, the rotation drive units 43a, 43b each includes a motor. In the depicted example, the motors of the rotation drive units 43a, 43b are arranged under a floor panel of the housing 41, the motor of the rotation drive unit denoted by the reference sign 43a and the rollers denoted by the reference signs 42a, 42d are supported on one drive device attachment base 46, and the motor of the rotation drive unit denoted by the reference sign 43b and the rollers denoted by the reference signs 42b, 42c are supported on another drive device attachment base 46. Each drive device attachment base 46 is structured to be able to change position by sliding in up-down directions with respect to an attachment support member 47 fixed to the floor panel of the housing 41, and the attachment support member 47 is designed to be sandwiched between the drive device attachment base 46 and the floor panel of the housing 41 when the cleaning device 16 is operating. Accordingly, when the cleaning device 16 is operating, vibrations occurring due to a notch or an orientation flat (not shown) on the outer edge of the substrate W hitting the rollers 42a to 42d are transmitted from the rollers 42a to 42d to the drive device attachment bases 46 and the attachment support members 47.

In the depicted example, the motor of the rotation drive unit denoted by the reference sign 43a rotationally drives the rollers denoted by the reference signs 42a, 42d via a pulley and a belt, and the motor of the rotation drive unit denoted by the reference sign 43b rotationally drives the rollers denoted by the reference signs 42b, 42c via a pulley and a belt. The plurality of rollers 42a to 42d are rotationally driven in the same directions (counterclockwise, in the example depicted in FIG. 3) by the rotation drive units 43a, 43b, whereby the substrate W held by the plurality of rollers 42a to 42d is rotated in an opposite direction (clockwise, in the example depicted in FIG. 3) to the direction in which each of the rollers 42a to 42d rotates, due to frictional force acting between each of the rollers 42a to 42d and the outer edge of the substrate W.

Although the cleaning members 44a, 44b are columnar roll cleaning members (roll sponges) elongated to have a long-length shape and formed of, for example, polyvinyl alcohol (PVA) in the present embodiment, the cleaning members 44a, 44b are not limited thereto, and may be a columnar pencil cleaning member extending in the vertical direction, or may be a buff cleaning polishing member with an axis line of rotation extending in the vertical direction.

As shown in FIG. 2, the plurality of rollers 42a to 42d, the cleaning members 44a, 44b, and the cleaning liquid supply nozzle 45 are arranged inside the housing 41, and the cleaning liquid supplied onto the substrate W is prevented from splashing to the outside of the cleaning space.

As shown in FIG. 2, the substrate support device 50 according to the present embodiment includes: a vibration transmission mechanism 70 that is installed in such a manner as to extend from the rollers 42a to 42d or the rotation drive units 43a, 43b up to the housing 41, and that transmits, to the housing 41, vibrations occurring due to the notch or the orientation flat (not shown) on the outer edge of the substrate W hitting the rollers 42a to 42d; a detection sensor 51 that is arranged outside the housing 41, and that detects at least one of sound, vibration, and strain occurring from the housing 41, and outputs a signal corresponding thereto; and a rotation speed calculation section 52 that calculates the rotation speed of the substrate W, based on the signal outputted from the detection sensor 51.

As an embodiment of the rotation speed calculation section 52, a rotation speed calculation circuit can be adopted, and a configuration can be made in such a manner that the rotation speed calculation circuit and a rotation speed setting circuit as a rotation speed setting section 56 are provided in the controller 30. In the embodiment, the rotation speed calculation circuit can be configured to: (i) receive a signal outputted from the detection sensor 51; (ii) read, from the rotation speed setting circuit as the rotation speed setting section 56, a rotation speed set value stored beforehand in the rotation speed setting circuit; (iii) then perform operation processing, which will be described later, and calculate the rotation speed of the substrate W corresponding to a value of the received signal from the detection sensor 51, through comparison of a result of the operation processing with the rotation speed set value; and (iv) output, to a display control section 53, a signal corresponding to the rotation speed of the substrate that is a result of the calculation.

For the rotation speed set value stored beforehand in the rotation speed setting circuit as the rotation speed setting section 56, a value that is set at the time of initial calibration can be used in the embodiment.

For the detection sensor 51, for example, at least one of a microphone, a vibration sensor, and a strain sensor (hereinafter, also referred to as “second strain sensor” in some cases) is used. In the case of a microphone, the detection sensor 51 may be arranged in close contact with an outer panel of the housing 41, or may be arranged away from the outer panel of the housing 41, as long as sound occurring from the housing 41 can be detected at a position where the detection sensor 51 is arranged. In the case of a vibration sensor, the detection sensor 51 is arranged in close contact with the outer panel of the housing 41 so that vibration occurring from the housing 41 can be detected. In the case of a strain sensor, the detection sensor 51 is attached to the outer panel of the housing 41 so that strain occurring in the housing 41 can be detected. It is desirable that the detection sensor 51 be arranged in a vicinity of an end portion of the vibration transmission mechanism 70 so that vibrations transmitted from the vibration transmission mechanism 70 to the housing 41 can be efficiently detected.

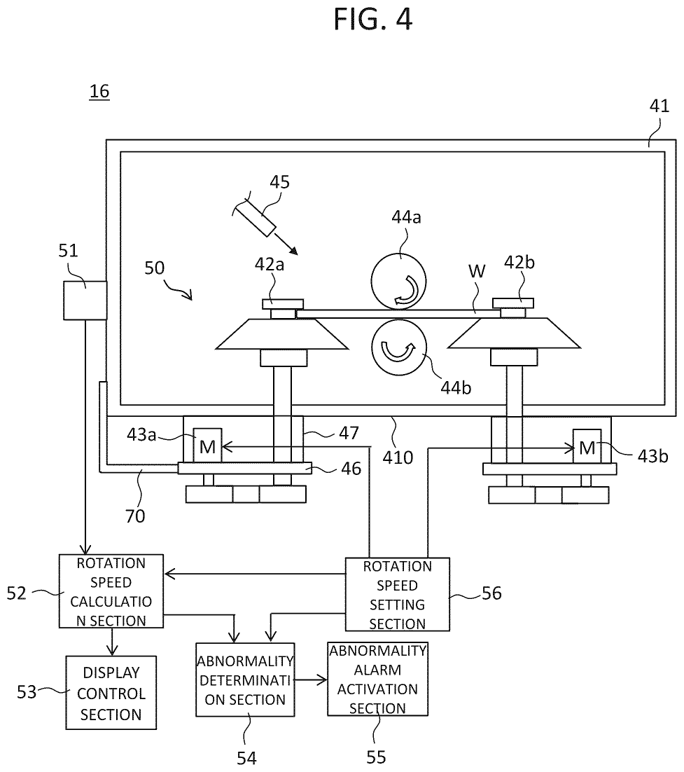

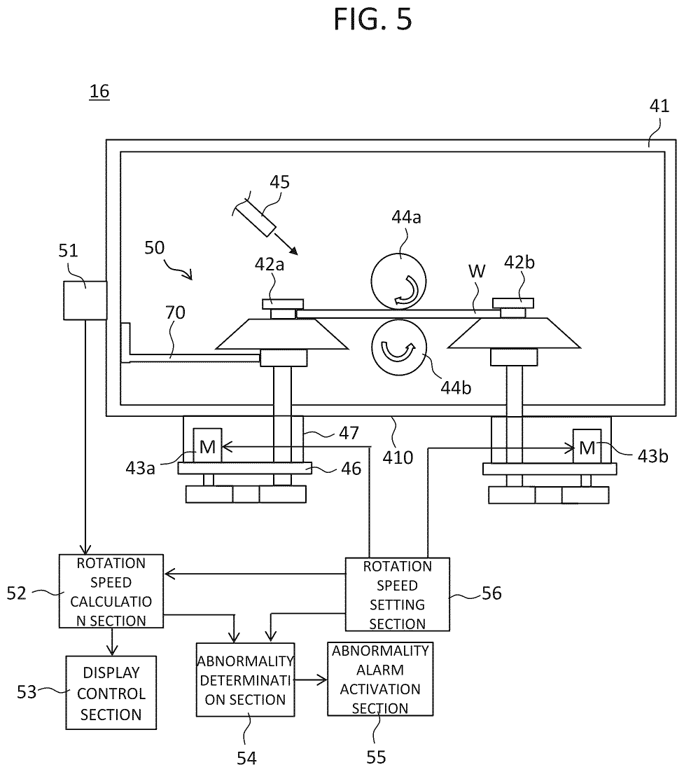

In the depicted example, the vibration transmission mechanism 70 has an elongated rod (bar) shape, one end of which is in direct contact with the rollers 42a to 42d or the rotation drive units 43a, 43b, and the other end of which is in direct contact with the housing 41. Thus, the rollers 42a to 42d or the rotation drive units 43a, 43b and the housing 41 are connected via a solid object that is the vibration transmission mechanism 70. The vibration transmission mechanism 70 may be arranged outside or may be arranged inside the housing 41. In the example depicted in FIG. 2, one end of the vibration transmission mechanism 70 is fixed to (or is in contact, in an unfixed manner, with) the attachment support member 47, which is arranged in such a manner as to be sandwiched between the drive device attachment base 46 and the floor panel of the housing 41, and the other end is fixed to the outer panel of the housing 41 from outside. As a modification, as shown in FIG. 4, one end of the vibration transmission mechanism 70 may be fixed to (or is in contact, in an unfixed manner, with) the drive device attachment base 46, and the other end may be fixed to the outer panel of the housing 41 from outside. As another modification, as shown in FIG. 5, one end of the vibration transmission mechanism 70 may be fixed to (or is in contact, in an unfixed manner, with) a bearing (or a support) of the roller 42a, and the other end may be fixed to (or is in contact, in an unfixed manner, with) the outer panel of the housing 41 from inside.

For the vibration transmission mechanism 70, for example, a round rod, a square rod, an extruded material with any one of various cross-section shapes such as L, H, and I shapes, a pipe, a bent material made by bending a plate, or the like is used. When the vibration transmission mechanism 70 is arranged inside the housing 41, it is desirable that a material of the vibration transmission mechanism 70 be a chemical-resistant resin. When the vibration transmission mechanism 70 is arranged outside the housing 41, a material of the vibration transmission mechanism 70 may be resin or may be metal unless restrictions in use are imposed.

The natural frequency of the vibration transmission mechanism 70 may be adjusted to correspond to the frequency of vibrations occurring due to the notch or the orientation flat on the outer edge of the substrate W hitting the rollers 42a to 42d. As the rotation speed of the substrate W increases, the frequency of vibrations occurring due to the notch or the orientation flat on the outer edge of the substrate W hitting the rollers 42a to 42d also becomes higher. The vibration transmission mechanism 70 has a natural frequency, and vibrations are amplified in bands around the frequency and are damped in higher frequency bands than the frequency. Accordingly, by adjusting the natural frequency of the vibration transmission mechanism 70, required vibration components can be selected or emphasized, and frequency components of vibrations occurring according to the rotation speed of the substrate W can be easily transmitted. Natural frequency is proportional to a modulus of direct elasticity to the power of one half, and is inversely proportional to a density to the power of one half. For example, the natural frequency f₀ of a rod shape with a constant cross-section area is expressed by a following expression (1):

$${f}_{0} = ( n / 2 L ) \cdot {( E / μ )}^{1 / 2} \qquad ( 1 )$$

where n is a natural number, L is the length of the rod, E is the modulus of direct elasticity, and μ is the density.

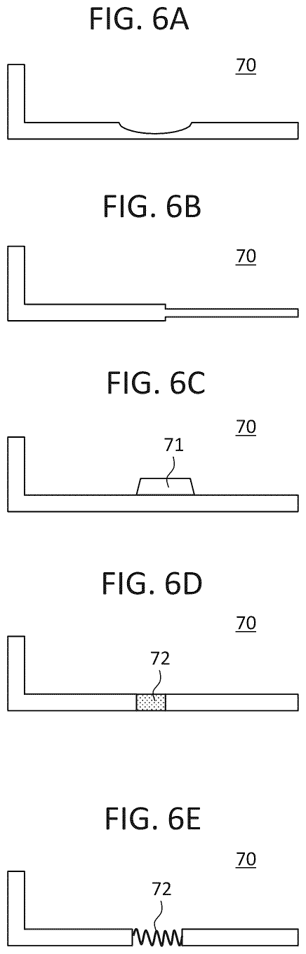

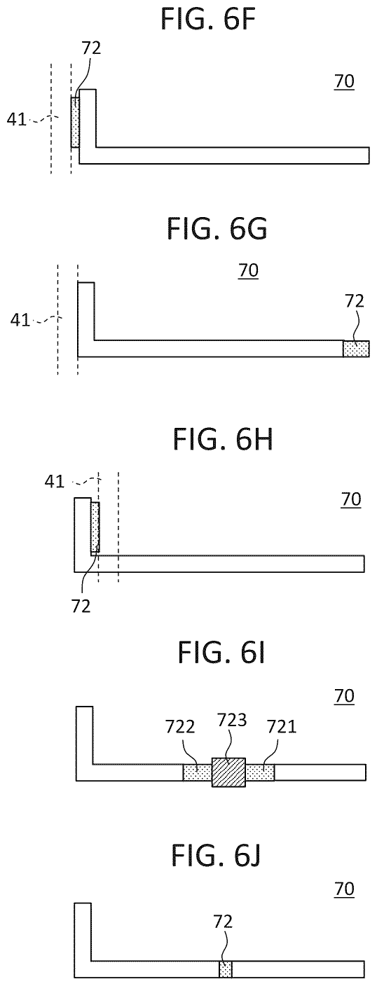

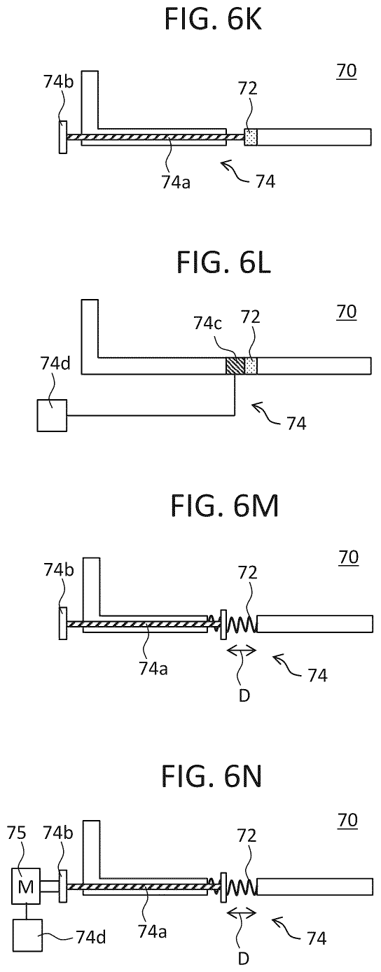

For example, at least one of a material (resin, metal), the length, and the cross-section shape of the vibration transmission mechanism 70 may be adjusted as shown in FIGS. 6A and 6B or a mass 71 may be added to part in a longitudinal direction of the vibration transmission mechanism 70 as shown in FIG. 6C so that the natural frequency of the vibration transmission mechanism 70 corresponds to the frequency of vibrations occurring due to the notch or the orientation flat on the outer edge of the substrate W hitting the rollers 42a to 42d.

As a modification, as shown in FIGS. 6D and 6E, part in the longitudinal direction of the vibration transmission mechanism 70 may be configured by using an elastic object 72. The elastic object 72 may be rubber as shown in FIG. 6D, or may be a spring material such as a coiled spring as shown in FIG. 6E. The natural frequency of the elastic object 72 is lower than those of high-stiffness materials such as metal. Accordingly, by configuring part in the longitudinal direction of the vibration transmission mechanism 70 by using the elastic object 72, the natural frequency of the vibration transmission mechanism 70 is decreased. Thus, only low-frequency vibrations (vibrations occurring due to a low rotation speed) can be made to be easily transmitted and emphasized. For example, in a case where part in a longitudinal direction of a rod shape with a constant cross-section area is configured by using an elastic object, natural frequency f₀ is expressed by a following expression (2):

$${f}_{0} = ( {λ}_{i} / 2 π L ) \cdot {( E / μ )}^{1 / 2} \qquad ( 2 )$$

where λᵢ satisfies a following expression (3):

$$cot {λ}_{i} = - {( kL / AE )}^{1 / λ i} \qquad ( 3 )$$

where k is the spring rate of the elastic object, L is the length of the rod, A is the cross-section area, E is the modulus of direct elasticity, and μ is the density. λ₁ has values ranging from π/2 to π. Accordingly, the natural frequency f₀ expressed by the expression (2) is 1 to ½ times the natural frequency f₀ expressed by the expression (1). In other words, by configuring part in the longitudinal direction of the vibration transmission mechanism 70 by using the elastic object 72, the natural frequency of the vibration transmission mechanism 70 can be decreased approximately by half. λ₂ and subsequent λᵢ have values ranging from 3π/2 to 2π, from 5π/2 to 3π, from 7π/2 to 4π, . . . , respectively.

Although the elastic object 71 is arranged in the middle in the longitudinal direction of the vibration transmission mechanism 70 in the examples depicted in FIGS. 6D and 6E, the position of the elastic object 71 is not limited thereto. For example, the elastic object 72 may be arranged at an end portion of the vibration transmission mechanism 70 that is in direct contact with the rollers 42a to 42d or the rotation drive units 43a, 43b as shown in FIG. 6G, may be arranged at an end portion of the vibration transmission mechanism 70 that is in direct contact with the outer panel of the housing 71 from inside as shown in FIG. 6F, or may be arranged at an end portion that is in direct contact with the outer panel of the housing 71 from outside as shown in FIG. 6H. When the vibration transmission mechanism 70 penetrates through the outer panel of the housing 41 as shown in FIG. 6H, sufficient sealing is applied so that gas and liquid do not leak between the inside and the outside of the housing 41 in both directions.

As another modification, as shown in FIG. 6I, part in the longitudinal direction of the vibration transmission mechanism 70 may be configured by using a pair of elastic objects 721, 722, and a mass body 723 may be sandwiched between the pair of elastic objects 721, 722. In such a case, the natural frequency f₀ of the vibration transmission mechanism 70 is expressed by a following expression (4):

$${f}_{0} = ( 1 / 2 π ) \cdot {( ( {k}_{1} + {k}_{2} ) / m )}^{1 / 2} \qquad ( 4 )$$

where k₁, k₂ are the spring rates of the elastic objects, and m is the mass of the mass body. Accordingly, the effect of the elastic objects is dominant, and the natural frequency of the vibration transmission mechanism 70 expressed by the expression (4) can be made further lower than the natural frequency f₀ expressed by the expression (2).

As another modification, as shown in FIG. 6J, part in the longitudinal direction of the vibration transmission mechanism 70 may be configured by using the elastic object 72, and the elastic object 72 may be compressed. By compressing the elastic object 72, the stiffness of the elastic object 72 increases, reflection at joint portions thereof decreases, and loss in vibration transmission is therefore reduced.

As another modification, as shown in FIGS. 6K to 6M, part in the longitudinal direction of the vibration transmission mechanism 70 may be configured by using the elastic object 72, and an adjustment mechanism 74 may be provided that adjusts the amount of compression or the active length of the elastic object 72.

In the example depicted in FIG. 6K, the elastic object 72 is rubber, and the adjustment mechanism 74 includes a threaded rod 74a, a tip of which is in direct contact with the elastic object 72, and a dial 74b fixed to a proximal end portion of the threaded rod 74b. By rotating the dial 74b, the threaded rod 74a is rotated and slides in right and left directions of the plane of paper, whereby the amount of extrusion by which the tip of the threaded rod 74a extrudes the elastic object 72 (that is, the amount of compression of the elastic object 72) is adjusted.

In the example depicted in FIG. 6L, the elastic object 72 is rubber, and the adjustment mechanism 74 includes: a piezoelectric device 74c arranged in such a manner as to be inserted in part in the longitudinal direction of the vibration transmission mechanism 70; and an adjustment unit 74d that supplies voltage to the piezoelectric device 74c. The adjustment unit 74d may be implemented by a computer. By supplying voltage (an adjustment signal) from the adjustment unit 74d to the piezoelectric device 74c, the piezoelectric device 74c is deformed, whereby the amount of extrusion by which the piezoelectric device 74a extrudes the elastic object 72 (that is, the amount of compression of the elastic object 72) is adjusted.

In the example depicted in FIG. 6M, the elastic object 72 is a coiled spring, and the adjustment mechanism 74 includes the threaded rod 74a, a tip of which spirally moves along the spring, and the dial 74b fixed to a proximal end portion of the threaded rod 74b. By rotating the dial 74b, the threaded rod 74a is rotated, and the tip of the threaded rod 74a spirally moves along the spring, whereby the active length D of the elastic object 72 (coiled spring) is adjusted.

To supplement the description, the spring rate k of a coiled spring is expressed by a following expression (5):

$$k = P / δ = ( G \cdot {d}^{4} ) / ( 8 \cdot Na \cdot D ) \qquad ( 5 )$$

where P is a load applied to the spring, δ is the deflection of the spring, G is a shear modulus, Na is the number of active coils, D is a mean coil diameter, and d is a wire diameter. In other words, the spring rate k is inversely proportional to the number of active coils Na of the spring. Since the number of active coils Na of the spring is proportional to the length of the spring, the spring rate k can be adjusted by changing the length effectively working as a spring (active length D), whereby the natural frequency of the vibration transmission mechanism 70 can be adjusted.

As shown in FIG. 6N, a motor 75 may be connected to the dial 74b via an undepicted gear, and the motor 75 may rotate the dial 74b by a predetermined amount according to an adjustment signal sent from the adjustment unit 74d, whereby the active length D of the elastic object 72 (coiled spring) may be adjusted.

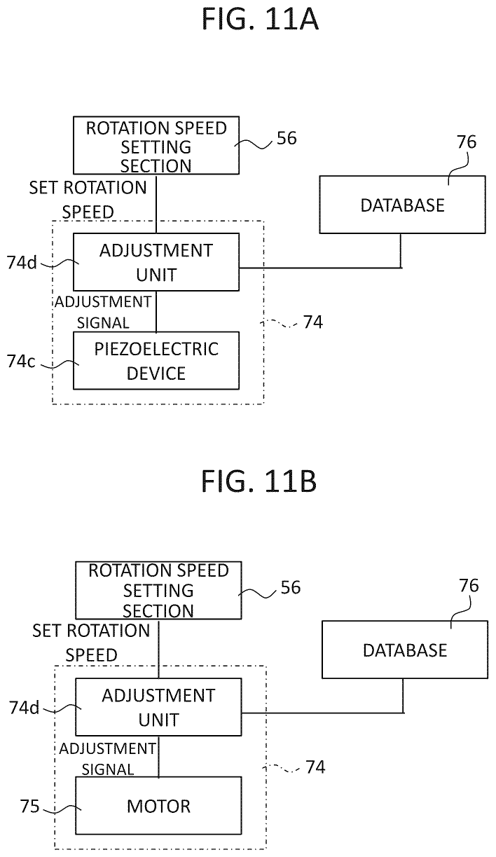

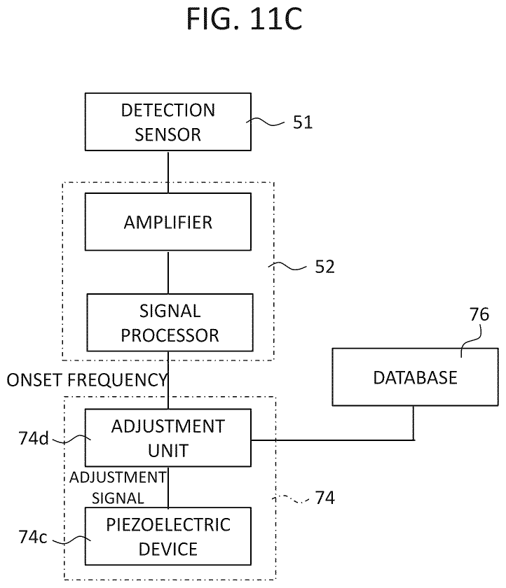

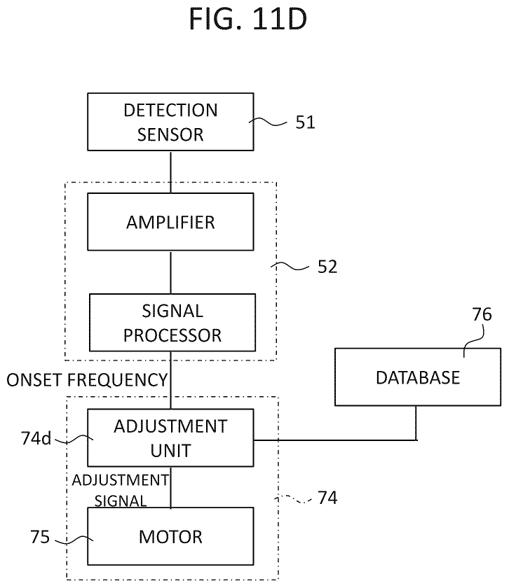

As shown in FIGS. 11A and 11B, the adjustment unit 74d of the adjustment mechanism 74 may acquire a set value of the rotation speed of the substrate W from the rotation speed setting section 56, which will be described later, may refer to a database 76 in which correspondences between rotation speeds and amounts of compression or active lengths are stored beforehand, and may send an adjustment signal to the piezoelectric device 74c (see FIG. 6L) or the motor 75 (see FIG. 6N) such that an amount of compression or an active length stored in the database 76 is achieved according to the set value of the rotation speed of the substrate W, whereby the amount of compression or the active length of the elastic object 72 may be adjusted. Thus, since the amount of compression or the active length of the elastic object 72 can be adjusted to an appropriate value according to the set value of the rotation speed of the substrate W, vibrations occurring due to the notch or the orientation flat on the outer edge of the substrate W hitting the rollers 42a to 42d can be appropriately emphasized and transmitted to the housing 41.

As a modification, as shown in FIGS. 11C and 11D, the adjustment mechanism 74 may adjust the amount of compression or the active length of the elastic object 41, according to the frequency of sound or vibration detected by the detection sensor 51. Specifically, for example, the adjustment unit 74d of the adjustment mechanism 74 may acquire information on the rotation speed of the substrate W calculated based on a sound or vibration signal detected by the detection sensor 51 from the rotation speed calculation section 52, which will be described later, may refer to the database 76 in which correspondences between rotation speeds and amounts of compression or active lengths are stored beforehand, and may send an adjustment signal to the piezoelectric device 74c (see FIG. 6L) or the motor 75 (see FIG. 6N) such that an amount of compression or an active length stored in the database 76 is achieved according to the rotation speed calculated by the rotation speed calculation section 52, whereby the amount of compression or the active length of the elastic object 72 may be adjusted. Thus, since the amount of compression or the active length of the elastic object 72 can be adjusted to an appropriate value according to the frequency of sound or vibration detected by the detection sensor 51, vibrations occurring due to the notch or the orientation flat on the outer edge of the substrate W hitting the rollers 42a to 42d can be appropriately emphasized and transmitted to the housing 41.

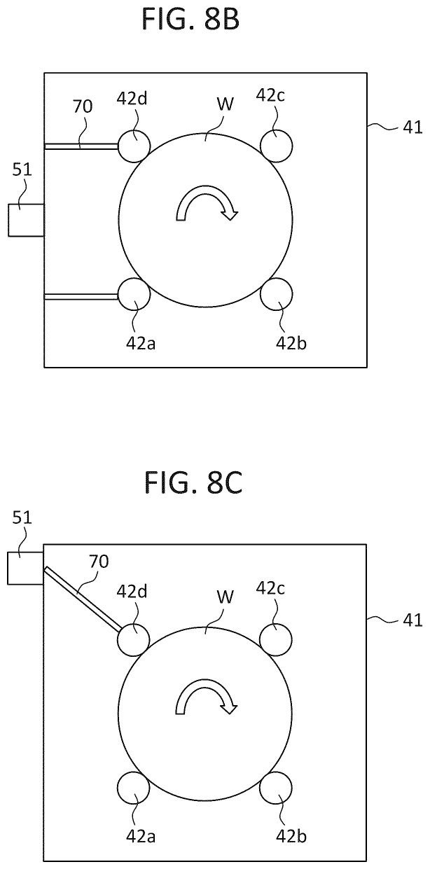

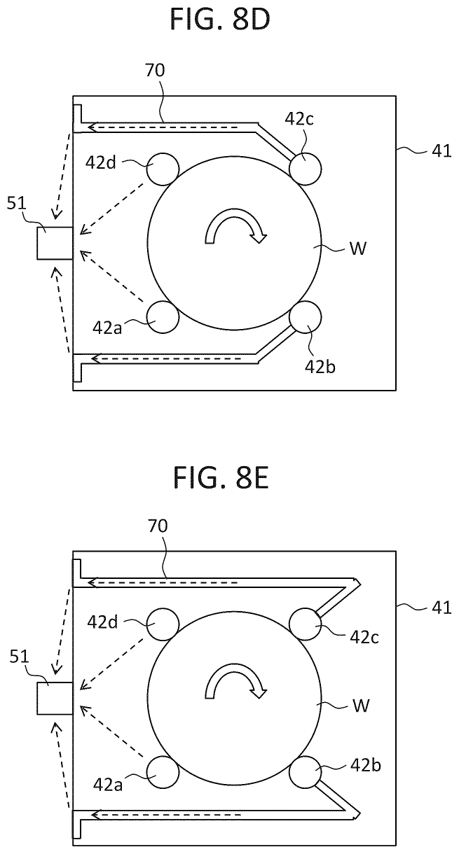

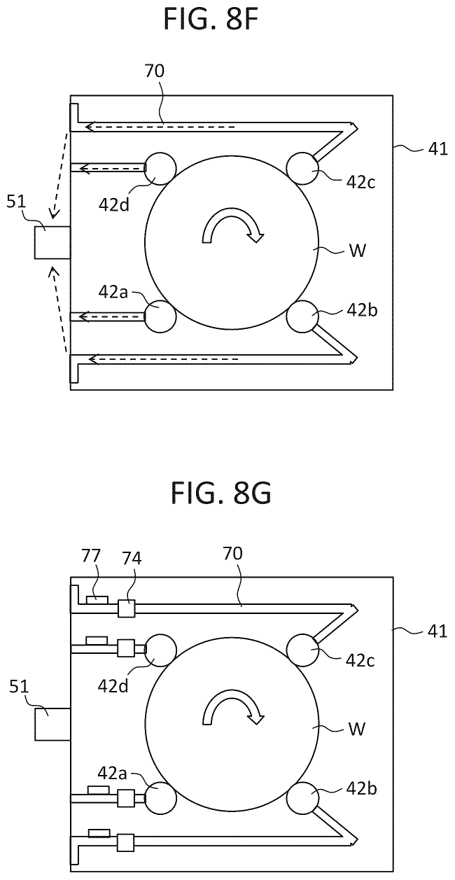

As another modification, referring to FIG. 8G, a strain gauge 77 may be attached to part in the longitudinal direction of the vibration transmission mechanism 70, and the adjustment unit 74d of the adjustment mechanism 74 may send an adjustment signal to the piezoelectric device 74c (see FIG. 6L) or the motor 75 (see FIG. 6N) according to a value detected by the strain gauge 77, whereby the amount of compression or the active length of the elastic object 42 may be adjusted.

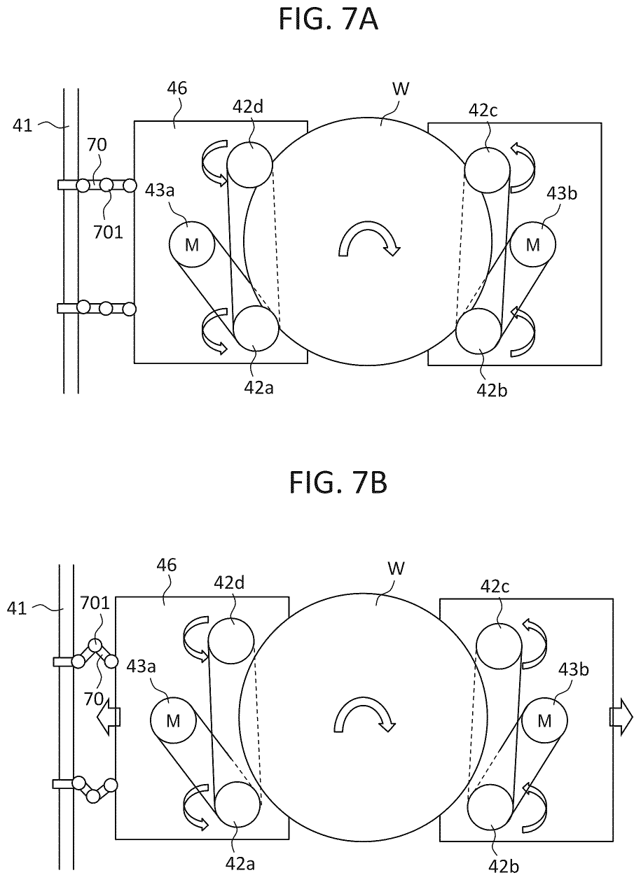

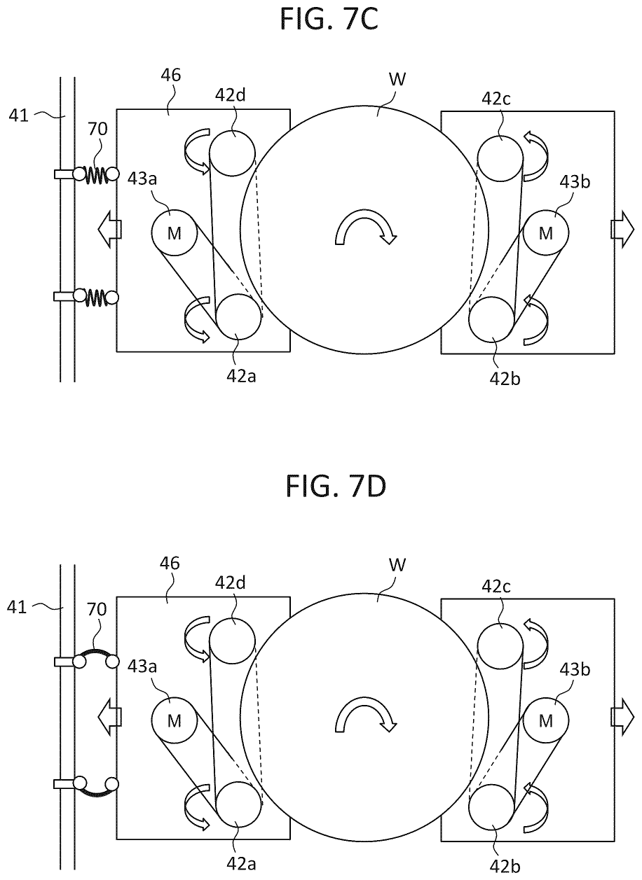

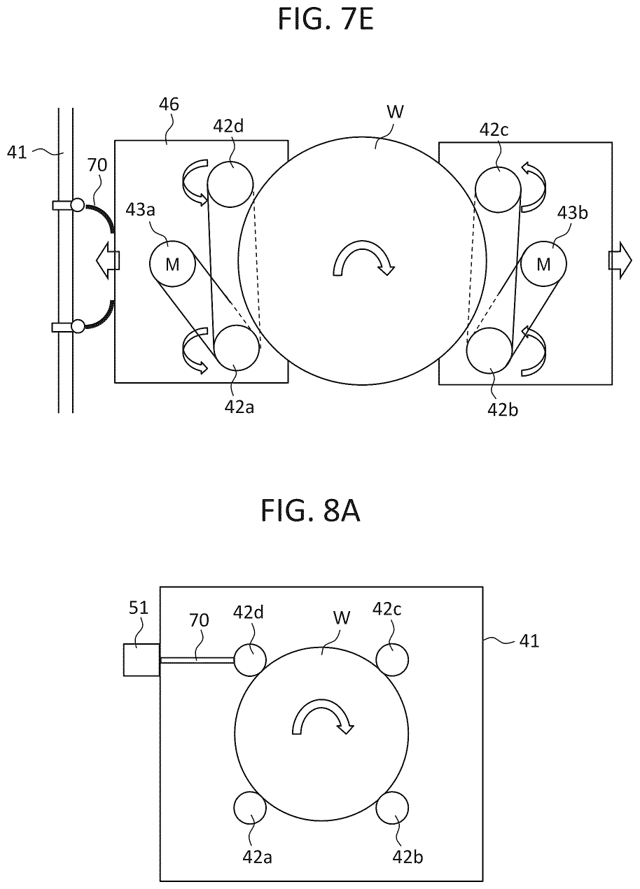

Incidentally, as shown in FIGS. 7A and 7B, when a substrate W is attached to or detached from the plurality of rollers 42a to 42d, such attachment or detachment needs to be performed by moving (moving in right and left directions, in the depicted example) the positions of the rollers 42a to 42d. Accordingly, as shown in FIGS. 7A and 7B, the vibration transmission mechanism 70 may include a pin joint part 701 that can be bent into an angle, and the pin joint part 701 may be configured to, even when the positions of the rollers 42a to 42d are changed, be bent into an angle accordingly and follow the movement of the rollers 42a to 42d. In such a case, when the substrate W is attached or detached, work of disconnecting the vibration transmission mechanism 70 once and reconnecting the vibration transmission mechanism 70 after the substrate W is attached is eliminated.

As a modification, as shown in FIG. 7C, the vibration transmission mechanism 70 may have a spring structure and may be configured to, even when the positions of the rollers 42a to 42d are changed, follow the movement of the rollers 42a to 42d as a result of the spring being compressed accordingly. Also in such a case, when the substrate W is attached or detached, work of disconnecting the vibration transmission mechanism 70 once and reconnecting the vibration transmission mechanism 70 after the substrate W is attached is eliminated.

As another modification, as shown in FIG. 7D, the vibration transmission mechanism 70 may have a structure (flexible structure) that can bend into a curve, and the vibration transmission mechanism 70 may be configured to, even when the positions of the rollers 42a to 42d are changed, bend into a curve accordingly and follow the movement of the rollers 42a to 42d. Also in such a case, when the substrate W is attached or detached, work of disconnecting the vibration transmission mechanism 70 once and reconnecting the vibration transmission mechanism 70 after the substrate W is attached is eliminated.

As another modification, as shown in FIG. 7E, the vibration transmission mechanism 70 may have a structure (flexible structure) that can bend into a curve, and may be in contact, in an unfixed manner, with the drive device attachment base 46, and even when the positions of the rollers 42a to 42d are changed, the vibration transmission mechanism 70 may be configured to bend into a curve accordingly, and an end portion thereof may be configured to slide along the drive device attachment base 46 and follow the movement of the rollers 42a to 42d. Also in such a case, when the substrate W is attached or detached, work of disconnecting the vibration transmission mechanism 70 once and reconnecting the vibration transmission mechanism 70 after the substrate W is attached is eliminated.

As shown in FIG. 8A, the number of the vibration transmission mechanisms 70 may be one, and the one vibration transmission mechanism 70 may be provided for one roller 42d. In such a case, accuracy in detection by the detection sensor 51 can be enhanced by strengthening a signal from the one roller 42d.

As a modification, as shown in FIG. 8B, the number of the vibration transmission mechanisms 70 may be two or more, and the individual vibration transmission mechanisms 70 may be provided for the different rollers 42a, 42d. In such a case, accuracy in detection by the detection sensor 51 can be enhanced by strengthening signals from the plurality of rollers 42d.

As shown in FIG. 8C, at least a roller 42d-side end portion of the vibration transmission mechanism 70 may be oriented in such a manner as to extend, in a plane view, in a direction perpendicular to a tangent line to the substrate W at a point where the substrate W is in contact with the roller 42d. Vibrations occurring due to reaction force received by the roller 42d from the substrate W are in the direction perpendicular to the tangent line to the substrate W at the point where the substrate W is in contact with the roller 42d. Accordingly, in such an aspect, the vibration transmission mechanism 70 can efficiently transmit, to the housing 41, vibrations occurring due to the notch or the orientation flat on the outer edge of the substrate W hitting the roller 42d.

As an example of planar arrangement of the vibration transmission mechanism 70, as shown in FIG. 8D, the vibration transmission mechanisms 70 may be provided only for the rollers 42c, 42b that are arranged at positions relatively far away from the detection sensor 51, of the plurality of rollers 42a to 42d. In such a case, since signals from the individual rollers 42a to 42d can be equalized by strengthening the signals from the rollers 42c, 42b arranged at the positions relatively far away from the detection sensor 51, the signals can be detected with accuracy by the single detection sensor 51.

As a modification, as shown in FIG. 8E, the vibration transmission mechanisms 70 may be provided only for the rollers 42c, 42b that are arranged at positions relatively far away from the detection sensor 51, of the plurality of rollers 42a to 42d, and at least end portions, on sides to the rollers 42c, 42b, of the vibration transmission mechanisms 70 may be oriented in such a manner as to extend, in a plane view, in directions perpendicular to tangent lines to the substrate W at points where the substrate W is in contact with the rollers 42c, 42b. In such a case, the vibration transmission mechanisms 70 can efficiently transmit, to the housing 41, vibrations occurring due to the notch or the orientation flat on the outer edge of the substrate W hitting the rollers 42c, 42b.

As another modification, as shown in FIG. 8F, the vibration transmission mechanisms 70 may be provided for all the rollers 42a to 42d, respectively. In such a case, the S/N ratio can be improved as a whole.

As another modification, as shown in FIG. 8G, the vibration transmission mechanisms 70 may be provided for all the rollers 42a to 42d, respectively, a strain gauge 77 (hereinafter, also referred to as “first strain gauge” in some cases) may be attached to each vibration transmission mechanism 70, and the adjustment mechanism 74 may be configured to adjust the amount of compression or the active length of an elastic object (not shown in FIG. 8G), according to values detected by the strain gauges 77. With such a configuration, a rotation speed can also be calculated by inputting signals detected by the strain gauges 77 into the rotation speed calculation section 52. Since no external noise is mixed in, the S/N ratio can be improved.

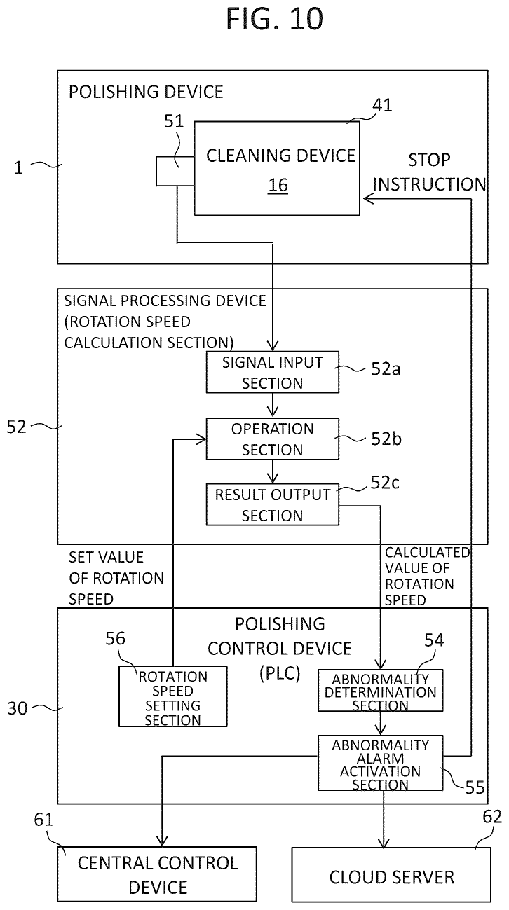

FIG. 10 is a block diagram showing a configuration of calculating the rotation speed (also referred to actual rotation speed) of a substrate W, based on sound or vibration detected by the detection sensor 51.

As shown in FIG. 10, the rotation speed calculation section 52 includes a signal input section 52a, an operation section 52b, and a result output section 52c, and calculates the rotation speed (actual rotation speed) of the substrate W, based on sound or vibration detected by the detection sensor 51. Here, the rotation speed calculation section 52 may calculate the rotation speed of the substrate W based on fundamental waves of the sound detected by the detection sensor 51, or may calculate the rotation speed of the substrate W based on fundamental waves and harmonics of the sound detected by the detection sensor 51.

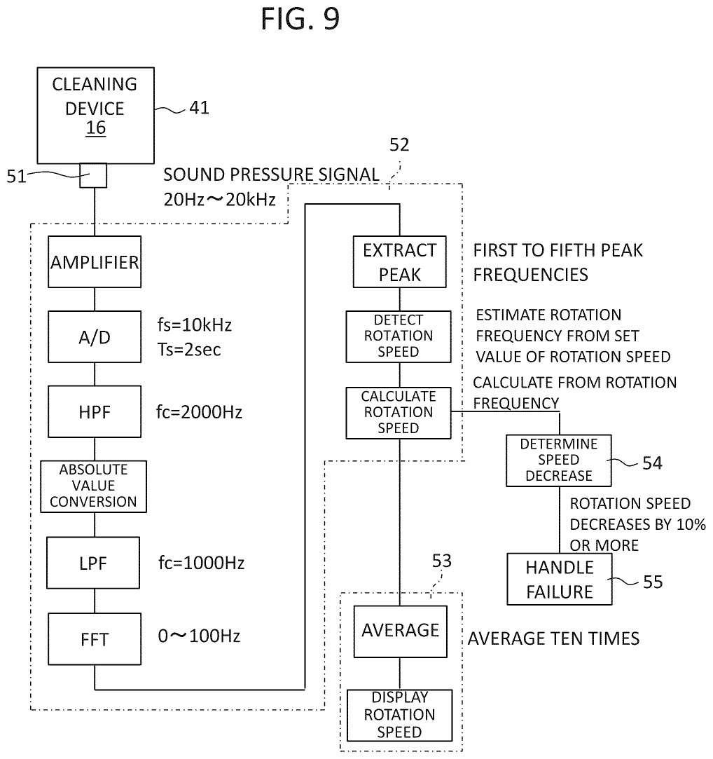

FIG. 9 is a diagram showing an example of a flow of signal processing of calculating the rotation speed (actual rotation speed) of the substrate W, based on sound or vibration detected by the detection sensor 51.

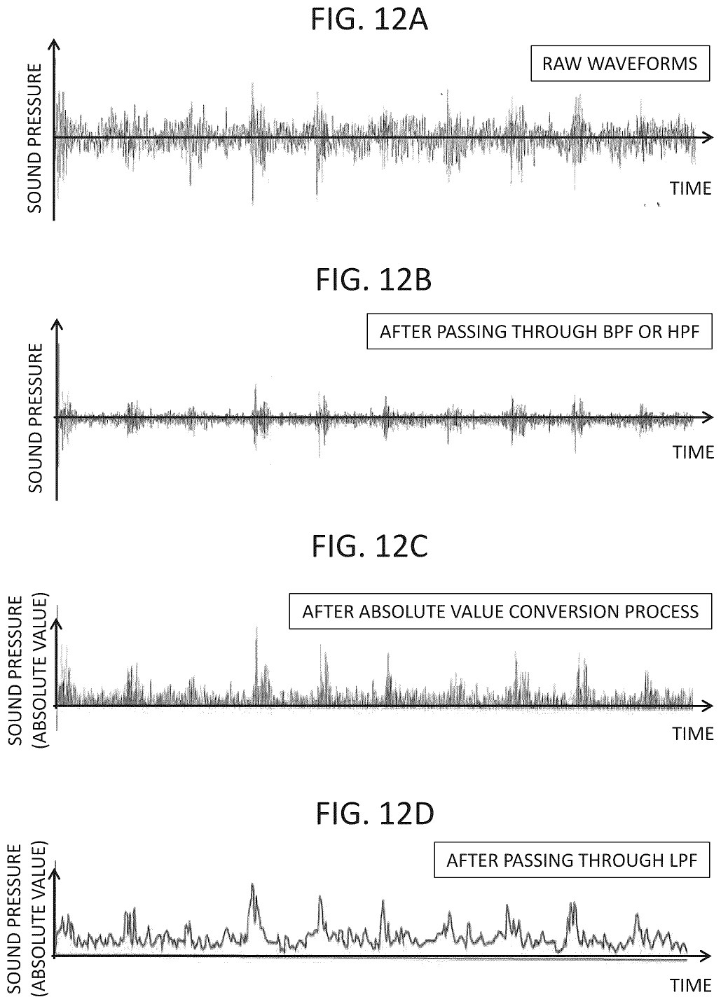

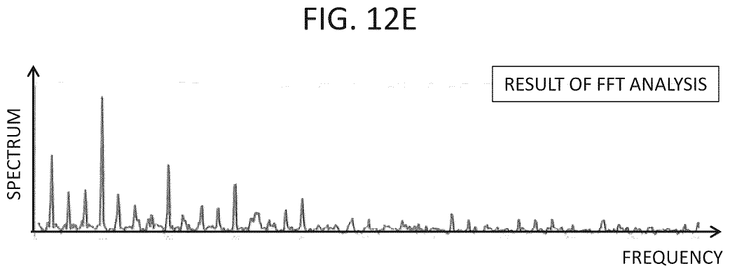

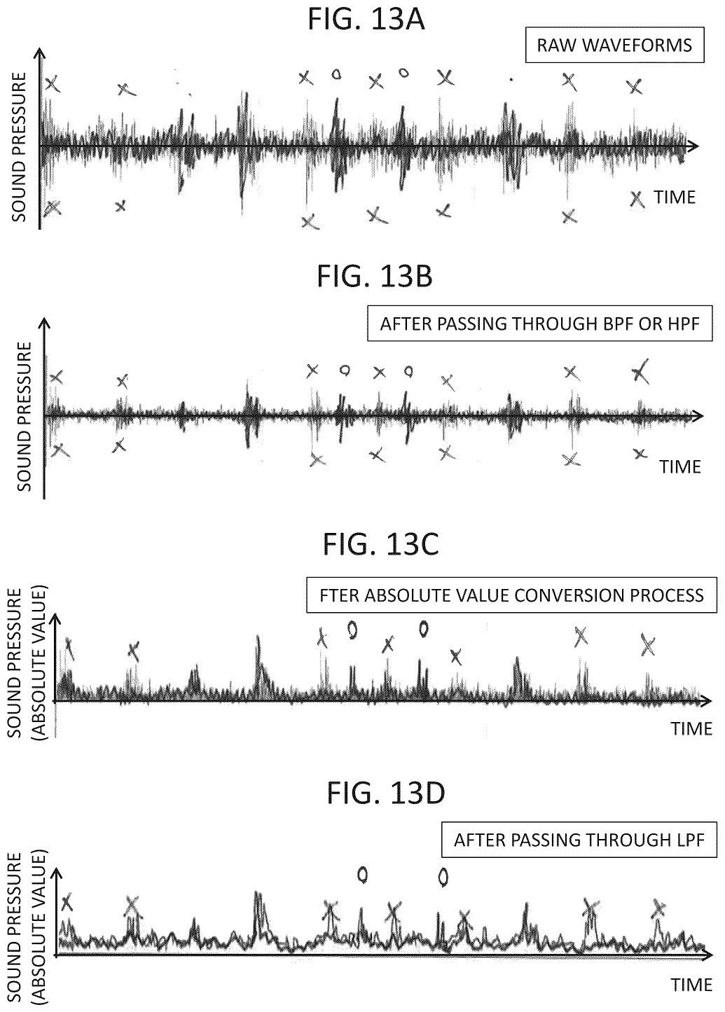

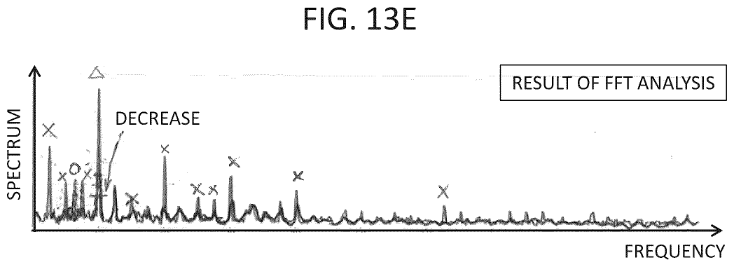

As shown in FIG. 9, the rotation speed calculation section 52 first amplifies a sound or vibration signal detected by the detection sensor 51 by using an amplifier, then performs analog-to-digital (A/D) conversion, and subsequently makes the signal pass through a band-pass filter (BPF) or a high-pass filter (HPF). As an example, in the A/D conversion, sampling frequency fs=10 kHz, sampling length Ts=2 sec, and HPF cutoff frequency fc=2000 Hz. FIG. 12A is an example of a graph showing raw waveforms (that is, waveforms before passing through the BPF or the HPF) of a sound or vibration signal detected by the detection sensor 51 at normal time, and FIG. 12B is an example of a graph showing waveforms, after passing through the BPF or the HPF, of the sound or vibration signal detected by the detection sensor 51 at normal time. FIG. 13A is an example of a graph showing raw waveforms of a sound or vibration signal detected by the detection sensor at abnormal time, superimposed on the raw waveforms of the sound or vibration signal detected by the detection sensor at normal time, and FIG. 13B is an example of a graph showing waveforms, after passing through the BPF or the HPF, of the sound or vibration signal detected by the detection sensor at abnormal time, superimposed on the waveforms, after passing through the BPF or the HPF, of the sound or vibration signal detected by the detection sensor at normal time. In FIGS. 13A and 13B, “x” indicates a place where a peak appearing at normal time disappears at abnormal time, and “◯” indicates a place of a peak that does not appear at normal time and is added at abnormal time.

Next, the rotation speed calculation section 52 performs an envelope process by performing absolute value conversion of the signal that has passed through the HPF and then making the signal pass through a low-pass filter (LPF). As an example, LPF cutoff frequency fc=1000 Hz. FIG. 12C is an example of a graph showing waveforms, after the absolute value conversion process, of the sound or vibration signal detected by the detection sensor 51 at normal time, and FIG. 12D is an example of a graph showing waveforms, after passing through the LPF, of the sound or vibration signal detected by the detection sensor 51 at normal time. FIG. 13C is an example of a graph showing waveforms, after the absolute value conversion process, of the sound or vibration signal detected by the detection sensor at abnormal time, superimposed on the waveforms, after the absolute value conversion process, of the sound or vibration signal detected by the detection sensor at normal time, and FIG. 13D is an example of a graph showing waveforms, after passing through the LPF, of the sound or vibration signal detected by the detection sensor at abnormal time, superimposed on the waveforms, after passing through the LPF, of the sound or vibration signal detected by the detection sensor at normal time. In FIGS. 13C and 13D, “x” indicates a place where a peak appearing at normal time disappears at abnormal time, and “◯” indicates a place of a peak that does not appear at normal time and is added at abnormal time.

Subsequently, the rotation speed calculation section 52 generates a frequency spectrum by performing fast Fourier transform (FFT) at, for example, 0 to 100 Hz on the signal that has passed through the LPF. The rotation speed calculation section 52 may generate a frequency spectrum by averaging a plurality of results of past FFT analyses. When the averaging is not performed, operation can be performed in a shorter time. FIG. 12E is an example of a graph showing a result of FFT analysis of the sound signal detected by the detection sensor 51 at normal time. FIG. 13E is a graph showing a result of FFT analysis of the sound or vibration signal detected by the detection sensor at abnormal time, superimposed on the result of FFT analysis of the sound or vibration signal detected by the detection sensor at normal time. In FIG. 13E, “x” indicates a place where a peak appearing at normal time disappears at abnormal time, and “◯” indicates a place of a peak that does not appear at normal time and is added at abnormal time. Referring to FIG. 13E, when the result of FFT analysis for normal time and the result of FFT analysis for abnormal time are compared, a frequency (a positional coordinate on a horizontal axis) corresponding to the peak (“◯”) appearing at abnormal time is a lower frequency than a frequency (positional coordinate) corresponding to a peak (“Δ”) at normal time, and frequency components of the frequency corresponding to the peak (“Δ”) at normal time are smaller. From such a fact, it can be found that the rotation speed of the substrate W decreases at abnormal time, compared to that at normal time.

Subsequently, the rotation speed calculation section 52 extracts a peak (for example, extracts first to fifth peak frequencies) from the generated frequency spectrum (the result of FFT analysis), estimates the rotation frequency of the substrate W based on the extracted peak frequencies and a set value of the rotation speed of the substrate W (also referred to as a set rotation speed) acquired from the rotation speed setting section 56, which will be described later, and calculates the rotation speed (actual rotation speed) of the substrate W from the estimated rotation frequency T.

The rotation speed calculation section 52 may change the cutoff frequency fc of a filter (that is, BPF, HPF, or LPF) applied to the sound or vibration signal detected by the detection sensor 51, depending on the set value of the rotation speed (set rotation speed) of the substrate W acquired from the rotation speed setting section 56.

The rotation speed calculation section 52 may change the cutoff frequency fc of a filter (that is, BPF, HPF, or LPF) applied to the sound signal detected by the detection sensor 51, depending on the type of cleaning liquid (for example, chemical liquid, detergent, water, or the like) or a characteristic value of a structure (for example, the rollers 42a to 42d).

As shown in FIG. 2, the substrate support device 50 according to the present embodiment is further provided with the rotation speed setting section 56, the display control section 53, an abnormality determination section 54, and an abnormality alarm activation section 55.

The rotation speed setting section 56 sets, on the rotation drive units 43a, 43b, a set value of the rotation speed (set rotation speed) of the substrate W. As described above, the rotation speed calculation section 52 may calculate the rotation speed (actual rotation speed) of the substrate W, with the set value of the rotation speed (set rotation speed) of the substrate W acquired from the rotation speed setting section 56, taken into consideration. Note that the rotation speed setting section 56 may be installed in the polishing control device 30 (see FIG. 1).

The display control section 53 causes a display (not shown) to display the rotation speed calculated by the rotation speed calculation section 52. The display control section 53 may cause the display to display the latest rotation speed calculated by the rotation speed calculation section 52, or may average a plurality of (for example, ten) past rotation speeds calculated by the rotation speed calculation section 52, and cause the display to display the average value.

The abnormality determination section 54 determines whether or not there is abnormality, based on the rotation speed calculated by the rotation speed calculation section 52. Here, the abnormality determination section 54 may determine whether or not there is abnormality, based on the average value of a plurality of (for example, ten) past rotation speeds calculated by the rotation speed calculation section 52. Abnormality determined by the abnormality determination section 54 may be a rotation abnormality (for example, occurrence of a slip), or any other abnormality (for example, an abnormality of a device).

Specifically, for example, the abnormality determination section 54 calculates a difference, or a ratio, between the rotation speed (actual rotation speed) calculated by the rotation speed calculation section 52 and the set value of rotation speed (set rotation speed) acquired from the rotation speed setting section 56, and determines that there is a rotation abnormality (for example, occurrence of a slip) when the difference or the ratio exceeds a predetermined threshold value (for example, when the actual rotation speed decreases by 10% or more, compared to the set rotation speed).

In the substrate support device 50, when the rollers 42a to 42d are worn out and the diameters thereof become small, the circumferential speed of the rollers 42a to 42d decreases, and the rotation speed of the substrate W therefore becomes gradually slower proportionately. Accordingly, the abnormality determination section 54 may calculate a difference or a ratio between the rotation speed (actual rotation speed) calculated by the rotation speed calculation section 52 and the set value of rotation speed (set rotation speed) acquired from the rotation speed setting section 56, and may determine that there is an abnormality of a device (for example, the rollers 42a to 42d are worn out) when the actual rotation speed gradually decreases compared to the set rotation speed.

Alternatively, for example, when the rotation speed (actual rotation speed) calculated by the rotation speed calculation section 52 is zero and the set value of rotation speed (set rotation speed) acquired from the rotation speed setting section 56 is not zero, or when abnormal sound is detected by the microphones 51a to 51c, the abnormality determination section 54 may determine that there is abnormality (for example, a crack of the wafer).

The abnormality determination section 54 may determine whether or not there is abnormality, with fluctuations in current flowing in the motors (not shown) that rotate the cleaning members 44a, 44b, taken into consideration. In such a case, by taking fluctuations in current flowing in the motors (not shown) that rotate the cleaning members 44a, 44b into consideration, an abnormality of any of the bearings or the like used in the rotation mechanism for the cleaning members 44a, 44b can be detected.

The abnormality determination section 54 may determine whether or not there is abnormality, with fluctuations in atmospheric pressure inside the housing 41 (for example, fluctuations in minute airflow around the notch or the orientation flat), taken into consideration.

The abnormality determination section 54 may determine whether or not there is abnormality, with fluctuations in pressing force of the rollers 42a to 42d against the outer edge of the substrate W, taken into consideration.

Referring to FIG. 10, when it is determined by the abnormality determination section 54 that there is abnormality, the abnormality alarm activation section 55 may activate an alarm to notify the abnormality to a central control device 61 or a cloud server 62, or may instruct the rotation drive units 43a, 43b to stop operating by sending a stop signal thereto.

Note that at least one or some of the rotation speed calculation section 52, the display control section 53, the abnormality determination section 54, and the abnormality alarm activation section 55 can be configured by using one or more computers.

Incidentally, as mentioned in the Background Art section, in order to determine whether or not a slip occurs between a substrate and a roller, there has conventionally been a method for measuring the actual rotation speed of the substrate by making an idler in contact with the outer edge of the substrate, but the method has the problem that cleanliness performance lowers, and the problem that the occurrence of erroneous measurement results from a slip occurring between the substrate and the idler.

Although the patent literature 1 discloses the technique in which vibrations occurring in rollers due to a notch or an orientation flat in a rotationally driven substrate hitting the rollers are detected by a vibration sensor attached to the rollers, and it is determined, based on detection of the vibrations, whether or not a slip occurs between the substrate and the rollers, the technique has the problem with maintainability because the vibration sensor for detecting vibrations is directly attached to the rollers.

To enhance maintainability, it is conceivable that the sensor is attached to an outer panel of the housing from outside. However, in such a case, the problem arises that sound or vibration occurring in external equipment outside the housing, and sound or vibration occurring inside the housing irrespective of the rotation speed of a substrate (for example, sound or vibration occurring due to cleaning liquid flowing, or the like) are mixed in as noise.

In contrast, according to the present embodiment as described above, since the detection sensor 51 is arranged outside the housing, maintainability is good. Moreover, the vibration transmission mechanism 70 is installed in such a manner as to extend from the rollers 42a to 42d or the rotation drive units 42a, 43d up to the outer panel of the housing 41, and transmits, to the housing 41, vibrations occurring due to a notch or an orientation flat on the outer edge of a substrate W hitting the rollers 42a to 42d. Accordingly, even though the detection sensor 51 is arranged outside the housing 41, the vibrations occurring due to the notch or the orientation flat on the outer edge of the substrate W hitting the rollers 42a to 42d are easily transmitted to the detection sensor 51, and the S/N ratio can be improved. Accordingly, accuracy in detection of the vibrations occurring due to the notch or the orientation flat on the outer edge of the substrate W hitting the rollers 42a to 42d can be enhanced, whereby it is possible to obtain the rotation speed of the substrate W with accuracy, while enhancing maintainability. Moreover, according to such an aspect, since the detection sensor 51 is arranged outside the housing 41, waterproof treatment is not required for the detection sensor 51, and further, even if burnable cleaning liquid is used inside the housing 41, explosion-proof treatment is not required for the detection sensor 51.

According to the present embodiment, since the natural frequency of the vibration transmission mechanism 70 is adjusted to correspond to the frequency of vibrations occurring due to the notch or the orientation flat on the outer edge of the substrate W hitting the rollers 42a to 42d, vibrations in bands around the natural frequency are amplified, and vibrations in higher frequency bands are damped in the vibration transmission mechanism 70. Accordingly, the vibrations occurring due to the notch or the orientation flat on the outer edge of the substrate W hitting the rollers 42a to 42d can be emphasized and transmitted to the housing 41, and accuracy in detection of the vibrations by the detection sensor 51 arranged outside the housing 41 can be enhanced.

According to the present embodiment, part in the longitudinal direction of the vibration transmission mechanism 70 is configured by using the elastic object 72, and therefore the natural frequency of the vibration transmission mechanism 70 decreases. Thus, only low-frequency vibrations (vibrations occurring due to a low rotation speed) can be made to be easily transmitted and emphasized.

According to the present embodiment, the elastic object 72 in the vibration transmission mechanism 70 is compressed, and therefore the stiffness of the elastic object 72 increases and reflection at a joint portion thereof decreases. Thus, loss in vibration transmission can be reduced.

According to the present embodiment, the amount of compression or the active length of the elastic object 72 can be adjusted by the adjustment mechanism 74, whereby the natural frequency of the vibration transmission mechanism 70 can be appropriately adjusted to correspond to the frequency of vibrations occurring due to the notch or the orientation flat on the outer edge of the substrate W hitting the rollers 42a to 42d.

### <Numerical Control System>

Next, a numerical control system 100 according to an embodiment is described.

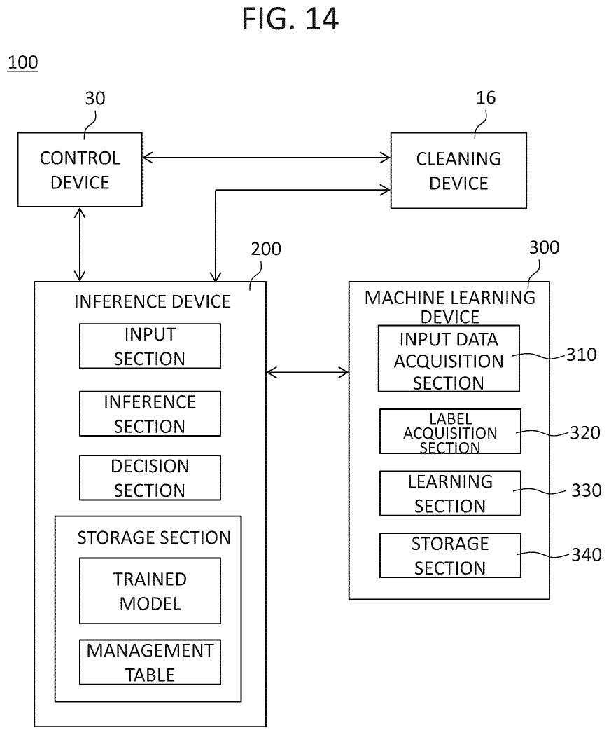

FIG. 14 is a functional block diagram showing an example of a functional configuration of the numerical control system 100 according to the embodiment. As shown in FIG. 14, the numerical control system 100 includes the control device 30, the cleaning device 16, an inference device 200, and a machine learning device 300. The control device 30, the cleaning device 16, the inference device 200, and the machine learning device 300 may be directly connected to each other via an undepicted connection interface. The devices may be connected to each other through an undepicted network such as a LAN (Local Area Network) or the Internet.

The control device 30 is a numerical control device commonly known to those skilled in the art, and generates an action command based on control information and sends the generated action command to the cleaning device 16. Thus, the control device 30 controls action of the cleaning device 16. The control device 30 also outputs the control information to the inference device 200. Note that the control information includes a cleaning recipe program and parameter values that are set on the control device 30.

The control device 30 may store, in an undepicted HDD (Hard Disk Drive) or the like, a list of identification information (hereinafter, also referred to as “substrate ID”) related to substrates that can be selected by the cleaning device 16, as a substrate data table. Note that the substrate data table may include substrate information associated with each substrate ID. The cleaning device 16 feeds back to the control device 30 information indicating an action state based on the action command from the control device 30.

The inference device 200 may acquire, from a sensor in the cleaning device 16, information on vibration, sound, or strain data, for example, selected by an operator of the control device 30. The inference device 200 can infer a degree of rotation abnormality of a selected substrate by inputting the sensing data acquired from the sensor and information related to substrate rotation into a trained model provided from the machine learning device 300, which will be described later.

A “degree of rotation abnormality of a substrate” indicates a degree of abnormality at a time of rotation of the substrate that is rotated in a cleaning process by the cleaning device 16. By using software in the control device 30, it is calculated, as an accumulated total time, how long the sensing data on vibration at the time of rotation of the substrate is out of a preset “safe area” during a predetermined time period (for example, 30 seconds) for which sensing is performed, and a degree of abnormality is determined by calculating a degree of rotation abnormality of the substrate, as a ratio of the calculated accumulated total time to the predetermined time period of sensing. For example, when the sensing data on vibration at the time of rotation of the substrate is out of the “safe area” for zero seconds during the predetermined 30-second time period of sensing, the “degree of rotation abnormality of the substrate” may be “0%”, and when the sensing data is out of the “safe area” for three seconds, the “degree of rotation abnormality of the substrate” may be “10%”.

The “degree of rotation abnormality of a substrate” increases at a time of high-speed rotation when a slip of the substrate easily occurs, and is “100%” when reworking is required to hold the substrate, or the like.

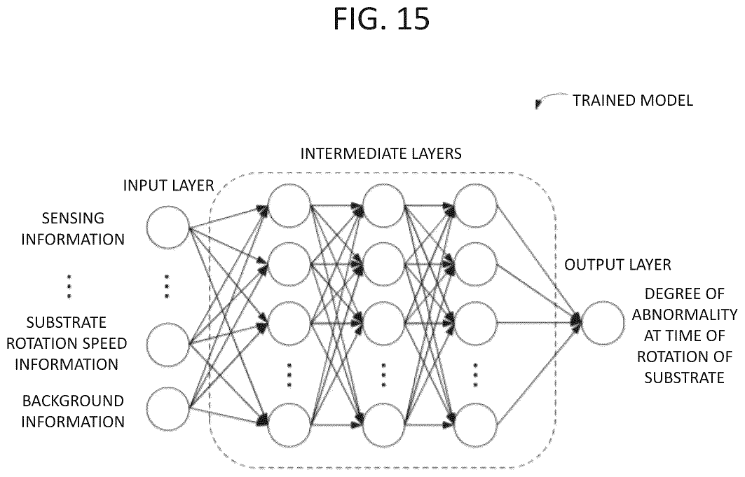

FIG. 15 is a diagram showing an example of the trained model provided from the machine learning device 300 to the inference device 200. Here, as shown in FIG. 15, the trained model is illustrated as a multi-layer neural network that takes, as input data to an input layer, basic process conditions serving as bases, such as the rotation frequency of a substrate and background information, and sensing information on vibration or the like obtained when any one selected substrate is rotated, and that produces, as output data from an output layer, data indicating a degree of rotation abnormality of the substrate when a specific sensing signal is obtained at a specific number of rotations.

Note that although the trained model in the example depicted in FIG. 15 is a multi-layer neural network that takes, as input data to the input layer, basic process conditions serving as bases, such as the rotation frequency of a substrate and background information, and sensing information on vibration or the like obtained when any one selected substrate is rotated, and that produces, as output data from the output layer, data indicating a degree of rotation abnormality of the substrate when a specific sensing signal is obtained at a specific number of rotations, the trained model is not limited thereto.

Next, the machine learning device 300 that builds such a trained model is described. The machine learning device 300 is implemented by one or more computers. As shown in FIG. 14, the machine learning device 300 includes an input data acquisition section 310, a label acquisition section 320, a learning section 330, and a storage section 340.

Of the sections, the storage section 340 is a RAM (Random Access Memory) or the like and stores input data acquired by the input data acquisition section 310, label data acquired by the label acquisition section 320, the trained model built by the learning section 300, and the like.

The input data acquisition section 310 acquires, as input data, past data (sensing data) obtained by the detection sensor based on at least one of sound, vibration, and strain occurring from the housing as a result of vibrations, which occur due to a notch or an orientation flat on the outer edge of a substrate hitting the rollers when the substrate held at the outer edge thereof by the rollers is rotationally driven in the housing of the cleaning device 15, being transmitted to the housing via the vibration transmission mechanism. The input data can be a moving average value of data obtained by the detection sensor based on at least one of sound, vibration, and strain during a predetermined time period from a time earlier than a reference time, which is freely set, until the reference time.

The storage section 340 stores data beforehand that indicates a degree of rotation abnormality of a substrate derived from the sensing data as the input data, and the label acquisition section 320 acquires the data as label data (correct data).

The learning section 330 receives pairs of input data and a label as described above, as training data (teaching data), performs supervised learning by using the received training data, and thereby builds a trained model that infers a degree of rotation abnormality of a substrate when the substrate is being rotated, based on substrate rotation speed data on workpieces to be cleaned and sensing data on the selected substrate. In one example, the learning section 330 may identify which one of a notch or an orientation flat is a source of vibrations at a time of rotation of a substrate, then may associate, with a degree of rotation abnormality in rotation of the substrate, data obtained by the detection sensor based on at least one of sound, vibration, and strain occurring from the housing, corresponding to the type of the source of vibrations, and may perform learning by using such associated data for teaching data. Such an example is preferable because, by doing so, knowledge of the presence or absence of vibration abnormality can be effectively learned from the teaching data, and highly accurate inference of a rotation abnormality level can therefore be achieved. The shape of a cut on the circumference of a wafer is different between a notch and an orientation flat. Since a notch is a small depression on the circumference of a wafer, a change in sensing data occurs once for an instant when the notch passes a roller, whereas an orientation flat is shaped by cutting off a partial section of the circumference of a wafer in a bow-like shape, and a change in sensing data therefore occurs twice with a small time interval in between when the orientation flat passes a roller. Respective patterns of changes over time in sensing data for the notch and the orientation flat are stored beforehand in the storage section 340, are acquired by the learning section 330, and are matched against sensing data, whereby it can be determined which one of a notch or an orientation flat is a source of vibrations.

When new teaching data is acquired after the trained model is built, the learning section 330 in the machine learning device 300 may update the trained model once built, by further performing supervised learning for the trained model.

The trained model may be shared with another machine learning device (not shown). If the trained model is shared between or among a plurality of machine learning devices 300, it is possible for each machine learning device 300 to perform supervised learning in a distributed manner, and it is possible to enhance efficiency in supervised learning.

Although some embodiments and modifications have been described for illustrative purposes hereinabove, the scope of the present technology is not limited thereto, and alterations and changes in form can be made according to purposes within the scope of claims. Each embodiment and each modification can be combined as appropriate to an extent that does not cause inconsistency in the content of the processes.

1. A substrate support device comprising:
a plurality of rollers that is arranged inside a housing and holds an outer edge of a substrate;
a rotation drive unit that rotates the substrate by rotationally driving the plurality of rollers;
a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller;
a detection sensor that is arranged outside the housing, detects at least one of sound, vibration, and strain occurring from the housing, and outputs a signal corresponding thereto; and
a rotation speed calculation section that calculates a rotation speed of the substrate, based on the signal outputted from the detection sensor.

2. The substrate support device according to claim 1, wherein natural frequency of the vibration transmission mechanism is adjusted to correspond to frequency of the vibrations occurring due to the notch or the orientation flat on the outer edge of the substrate hitting the roller.

3. The substrate support device according to claim 1 or 2, wherein part in a longitudinal direction of the vibration transmission mechanism is configured by using an elastic object.

4. The substrate support device according to claim 3, wherein the elastic object is compressed.

5. The substrate support device according to claim 3 or 4, comprising an adjustment mechanism that adjusts an amount of compression or an active length of the elastic object.

6. The substrate support device according to claim 5, wherein the adjustment mechanism refers to a database in which a correspondence between a rotation speed and an amount of compression or an active length is stored beforehand, and adjusts the amount of compression or the active length of the elastic object to the amount of compression or the active length stored in the database according to a set value of the rotation speed of the substrate.

7. The substrate support device according to claim 5, wherein the adjustment mechanism adjusts the amount of compression or the active length of the elastic object, according to a value detected by a first strain gauge attached to part in the longitudinal direction of the vibration transmission mechanism.

8. The substrate support device according to claim 5, wherein the adjustment mechanism adjusts the amount of compression or the active length of the elastic object, according to frequency of the signal outputted from the detection sensor.

9. The substrate support device according to claim 8, wherein the adjustment mechanism refers to a database in which a correspondence between a rotation speed and an amount of compression or an active length is stored beforehand, and adjusts the amount of compression or the active length of the elastic object to the amount of compression or the active length stored in the database according to the rotation speed calculated by the rotation speed calculation section.

10. The substrate support device according to any one of claims 1 to 9, wherein the detection sensor is at least one of a microphone, a vibration sensor, and a second strain gauge attached to the housing.

11. The substrate support device according to any one of claims 1 to 10, wherein at least an end portion, on a side to the roller or the rotation drive unit, of the vibration transmission mechanism is oriented in such a manner as to extend, in a plane view, in a direction perpendicular to a tangent line to the substrate at a point where the substrate is in contact with the roller.

12. The substrate support device according to any one of claims 1 to 11, wherein the rotation speed calculation section calculates the rotation speed of the substrate, based on a fundamental wave and a harmonic of the signal.

13. The substrate support device according to any one of claims 1 to 12, further comprising a rotation speed setting section that sets, on the rotation drive unit, a set value of the rotation speed of the substrate, wherein
the rotation speed calculation section calculates the rotation speed of the substrate, with the set value acquired from the rotation speed setting section taken into consideration.

14. The substrate support device according to any one of claims 1 to 13, further comprising a display control section that causes a display to display the rotation speed calculated by the rotation speed calculation section.

15. The substrate support device according to claim 14, wherein the display control section averages a plurality of past rotation speeds calculated by the rotation speed calculation section and causes the display to display a result thereof.

16. The substrate support device according to any one of claims 1 to 15, further comprising an abnormality determination section that determines whether or not there is abnormality, based on the rotation speed calculated by the rotation speed calculation section.

17. The substrate support device according to claim 16, wherein the abnormality determination section determines whether or not there is abnormality, based on an average value of a plurality of past rotation speeds calculated by the rotation speed calculation section.

18. The substrate support device according to claim 16 or 17, further comprising an abnormality alarm activation section that, when it is determined by the abnormality determination section that there is abnormality, activates an alarm about the abnormality and/or instructs the rotation drive unit to stop.

19. The substrate support device according to any one of claims 16 to 18, wherein the abnormality determination section calculates a difference or a ratio between the rotation speed calculated by the rotation speed calculation section and the set value acquired from the rotation speed setting section and, when the difference or the ratio exceeds a predetermined threshold value, determines that there is abnormality.

20. The substrate support device according to any one of claims 16 to 19, wherein the abnormality determination section determines that there is abnormality when the rotation speed calculated by the rotation speed calculation section is zero and the set value acquired from the rotation speed setting section is not zero, or when an abnormal signal is outputted from the detection sensor.

21. The substrate support device according to any one of claims 16 to 20, wherein the abnormality determination section determines whether or not there is abnormality, with fluctuations in current flowing in a motor rotating a cleaning member, taken into consideration.

22. The substrate support device according to any one of claims 16 to 21, wherein the abnormality determination section determines whether or not there is abnormality, with fluctuations in atmospheric pressure inside the housing, taken into consideration.

23. The substrate support device according to claim 13, wherein the rotation speed calculation section changes a cutoff frequency of a filter applied to the signal, according to the set value.

24. A polishing device comprising:
a plurality of rollers that holds an outer edge of a substrate;
a rotation drive unit that rotates the substrate by rotationally driving the plurality of rollers;
a cleaning member that comes into direct contact with the substrate and cleans the substrate;
a cleaning liquid supply nozzle that supplies cleaning liquid onto the substrate;
a housing that houses the plurality of rollers, the cleaning member, and the cleaning liquid supply nozzle;
a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller;
a detection sensor that is arranged outside the housing, detects at least one of sound, vibration, and strain occurring from the housing, and outputs a signal corresponding thereto; and
a rotation speed calculation section that calculates a rotation speed of the substrate, based on the signal outputted from the detection sensor.

25. A device that, in a substrate support device, calculates a rotation speed of a substrate, the substrate support device including: a plurality of rollers that is arranged inside a housing and holds an outer edge of the substrate; and a rotation drive unit that rotates the substrate by rotationally driving the plurality of rollers, the device comprising:
a vibration transmission mechanism that is installed in such a manner as to extend from any of the rollers or the rotation drive unit up to the housing and transmits vibrations to the housing, the vibrations occurring due to a notch or an orientation flat on the outer edge of the substrate hitting the roller;
a detection sensor that is arranged outside the housing, detects at least one of sound, vibration, and strain occurring from the housing, and outputs a signal corresponding thereto; and
a rotation speed calculation section that calculates the rotation speed of the substrate, based on the signal outputted from the detection sensor.

26. A method for calculating a rotation speed of a substrate for a substrate support device, the substrate support device including: a plurality of rollers that is arranged inside a housing and holds an outer edge of the substrate; and a rotation drive unit that rotates the substrate by rotationally driving the plurality of rollers, the method comprising:
by a vibration transmission mechanism installed in such a manner as to extend from any of the rollers or the rotation drive unit up to the housing, transmitting vibrations to the housing, the vibrations occurring due to a notch or an orientation flat on the outer edge of the substrate hitting the roller;
by a detection sensor arranged outside the housing, detecting at least one of sound, vibration, and strain occurring from the housing and outputting a signal corresponding thereto; and
calculating the rotation speed of the substrate, based on the signal outputted from the detection sensor.

27. The method according to claim 26, further comprising adjusting at least one of material of, length of, cross-section shape of, and mass addition to the vibration transmission mechanism in such a manner that natural frequency of the vibration transmission mechanism corresponds to frequency of the vibrations occurring due to the notch or the orientation flat on the outer edge of the substrate hitting the roller.

28. A machine learning device comprising:
a data acquisition section that acquires, as input data, data obtained by a detection sensor based on at least one of sound, vibration, and strain that occur from a housing as a result of vibrations being transmitted to the housing via a vibration transmission mechanism, the vibrations occurring due to a notch or an orientation flat on an outer edge of a substrate hitting a roller when the substrate held at the outer edge thereof by the roller is rotationally driven inside the housing;
a label acquisition section that acquires label data indicating a degree of rotation abnormality at a time of rotation of the substrate under a substrate rotation condition included in the input data; and
a learning section that generates a trained model by performing supervised learning using the input data acquired by the input data acquisition section and the label data acquired by the label acquisition section.

29. The machine learning device according to claim 28, wherein the input data is a moving average value of data obtained by the detection sensor based on at least one of sound, vibration, and strain during a predetermined time period from a time earlier than a reference time until the reference time.

30. The machine learning device according to claim 28, wherein the learning section identifies which one of the notch and the orientation flat is a source of the vibrations at the time of rotation of the substrate, associates, with the degree of rotation abnormality, the data obtained by the detection sensor based on at least one of sound, vibration, and strain that occur from the housing and correspond to a type of the source, and performs learning by using the associated data for teaching data.
